(19) United States
(12) Patent Application Publication
(10) Pub. No.: US 2014/0353837 A1
(43) Pub. Date: Dec. 4, 2014

(54) SEMICONDUCTOR DEVICE AND MANUFACTURING METHOD THEREOF

(71) Applicant: Kabushiki Kaisha Toshiba, Minato-ku (JP)

(72) Inventor: Takashi WATANABE, Yokkaichi-shi (JP)

(73) Assignee: Kabushiki Kaisha Toshiba, Minato-ku (JP)

(21) Appl. No.: 13/973,114

(22) Filed: Aug. 22, 2013

Related U.S. Application Data
(60) Provisional application No. 61/828,770, filed on May 30, 2013.

(51) Int. Cl. H01L 23/485; H01L 23/48; H01L 21/768

(52) U.S. Cl. CPC H01L 23/485; H01L 21/76802; H01L 23/481; H01L 21/76841
USPC 257/773; 438/637

(57) ABSTRACT

A semiconductor device according to the present embodiment includes an insulating film provided above a semiconductor substrate. A plurality of upper-layer wirings are provided on the insulating film. A plurality of lower-layer wirings are provided in the insulating film. The lower-layer wirings are respectively located between the upper-layer wirings adjacent to each other when viewed from above the semiconductor substrate. Side surfaces of the lower-layer wirings substantially match surfaces of the upper-layer wirings present on both sides of the lower-layer wirings, respectively when viewed from above the semiconductor substrate.

### CROSS REFERENCE TO RELATED APPLICATIONS

This application is based upon and claims the benefit of priority from the prior U.S. Provisional Patent Application No. 61/828,770, filed on May 30, 2013, the entire contents of which are incorporated herein by reference.

### FIELD

The embodiments of the present invention relate to a semiconductor device and a manufacturing method thereof.

### BACKGROUND

As semiconductor devices are increasingly downscaled, it is desired to form finer patterns than a minimum feature size (hereinafter, also “F (Feature Size)”) at which patterns can be formed by a lithographic technique and an etching technique. The development of a double patterning technique using a sidewall transfer method is underway so as to form such fine patterns.

In recent years, a method of repeating the sidewall transfer twice is proposed so as to meet the demand of further downscaling. However, the method of repeating the sidewall transfer twice has such problems as the increase in the number of manufacturing processes, the increase in the process irregularities, the rise in wiring resistance, and the increase in inter-wiring capacity.

Furthermore, with a conventional multilayer wiring structure, wirings are formed by performing lithography and dry etching for every wiring layer. Therefore, it is necessary to secure a margin for each wiring distance on each layer in light of possible misalignment. Accordingly, the conventional multilayer wiring structure has problems of the degradation in the integrity of wirings and eventually the increase in chip area.

### BRIEF DESCRIPTION OF THE DRAWINGS

FIGS. 1-1 and 1-2 are schematic plan views showing an example of a configuration of a semiconductor device according to a first embodiment;

FIG. 2A is a cross-sectional view of the memory region taken along a line A-A of FIG. 1-1;

FIG. 2B is a cross-sectional view of an end portion (a loop cut region) in the memory region taken along a line B-B of FIG. 1-1;

FIG. 2C is a cross-sectional view of the peripheral circuit region taken along a line C-C of FIG. 1-2;

FIGS. 3-1 to 14C are cross-sectional views showing the manufacturing method of the memory device according to the first embodiment;

FIG. 15 is a cross-sectional view showing air gaps AG each formed in the interlayer dielectric film 60 between the upper-layer wirings 40;

FIGS. 16A to 16C are cross-sectional views showing an example of a configuration of a memory device according to the second embodiment;

FIGS. 17A to 21C are cross-sectional views showing a manufacturing method of the memory device according to the second embodiment;

FIGS. 22A to 22C are cross-sectional views showing a specific example of the manufacturing method in a case where the misalignment occurs in the lithographic process at the time of forming the hard masks 70;

FIGS. 23A to 23C are cross-sectional views showing a manufacturing method of a memory device according to a modification of the second embodiment;

FIGS. 24A to 24C are cross-sectional views showing an example of a configuration of a memory device according to the third embodiment; and

FIGS. 25A to 28C are cross-sectional views showing a manufacturing method of the memory device according to the third embodiment.

### DETAILED DESCRIPTION

Embodiments will now be explained with reference to the accompanying drawings. The present invention is not limited to the embodiments. In the embodiments, “an upper direction” or “a lower direction” refers to a relative direction when a direction of a surface of a semiconductor substrate on which semiconductor elements are provided is assumed as “an upper direction”. Therefore, the term “upper direction” or “lower direction” occasionally differs from an upper direction or a lower direction based on a gravitational acceleration direction.

A semiconductor device according to the present embodiment includes an insulating film provided above a semiconductor substrate. A plurality of upper-layer wirings are provided on the insulating film. A plurality of lower-layer wirings are provided in the insulating film. The lower-layer wirings are respectively located between the upper-layer wirings adjacent to each other when viewed from above the semiconductor substrate. Side surfaces of the lower-layer wirings substantially match surfaces of the upper-layer wirings present on both sides of the lower-layer wirings, respectively when viewed from above the semiconductor substrate.

### First Embodiment

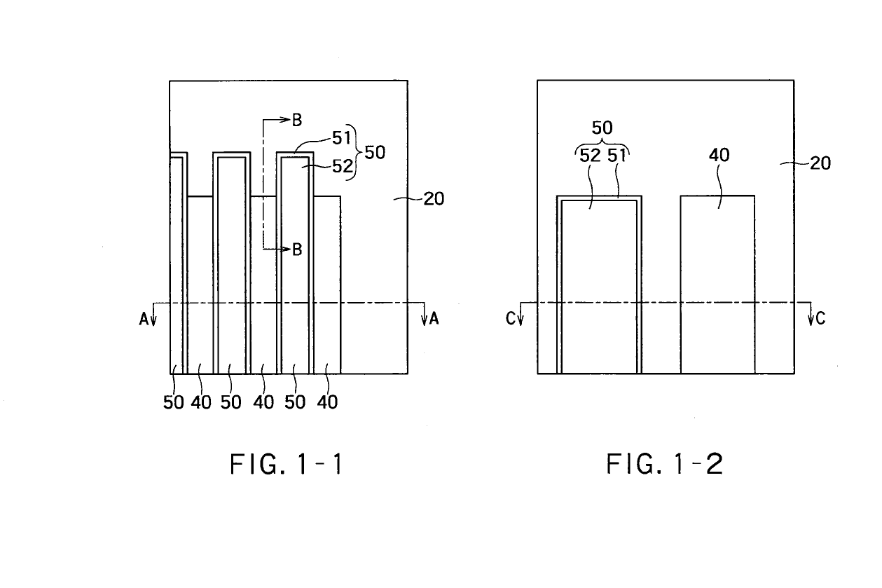

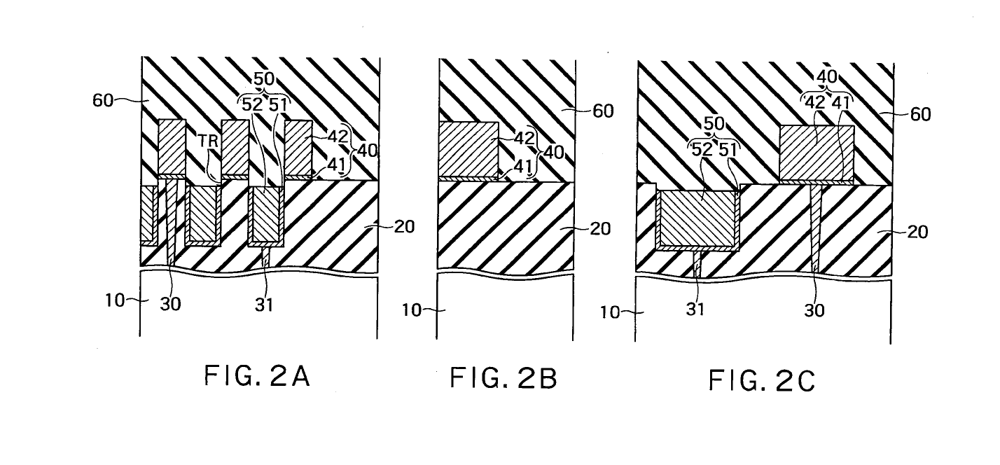

FIGS. 1-1 and 1-2 are schematic plan views showing an example of a configuration of a semiconductor device according to a first embodiment. FIG. 1-1 shows end portions of wirings in a memory region and FIG. 1-2 shows end portions of wirings in a peripheral circuit region. An interlayer dielectric film 60 is omitted in FIGS. 1-1 and 1-2.

FIG. 2A is a cross-sectional view of the memory region taken along a line A-A of FIG. 1-1. FIG. 2B is a cross-sectional view of an end portion (a loop cut region) in the memory region taken along a line B-B of FIG. 1-1. FIG. 2C is a cross-sectional view of the peripheral circuit region taken along a line C-C of FIG. 1-2. The lines A-A and C-C are in an orthogonal direction to an extension direction of upper-layer wirings 40 and lower-layer wirings 50 (hereinafter, “first direction”) on a surface of a semiconductor substrate 10. The line B-B is in a parallel direction to the first direction.

The semiconductor device according to the first embodiment is a semiconductor memory such as a NAND flash EEPROM (Electrically Erasable Programmable Read-Only Memory). However, the semiconductor device according to the first embodiment is not limited to the NAND flash EEPROM but also applicable to any semiconductor device that needs fine wirings.

As shown in FIGS. 2A to 2C, the semiconductor device according to the first embodiment includes the semiconductor substrate 10, a lower-layer insulating film 20, contact plugs 30 and 31, the upper-layer wirings 40, the lower-layer wiring 50, and the interlayer dielectric film 60. In the memory region and the peripheral circuit region on the surface of the semiconductor substrate 10, semiconductor elements such as memory cells, transistors, resistors, and capacitors are formed. These semiconductor elements are omitted in FIGS. 2A to 2C.

The lower-layer insulating film 20 is provided to cover the semiconductor elements above the semiconductor substrate 10. Each of the contact plugs 30 and 31 is provided in the lower-layer insulating film 20 and electrically connected to any one of the semiconductor elements. For example, in the memory region, the contact plug 30 or 31 is connected to one of the memory cells. For example, in the peripheral circuit region, the contact plug 30 or 31 is connected to one of the transistors.

As shown in FIG. 2A, a plurality of upper-layer wirings 40 are provided on the lower-layer insulating film 20. Each of the upper-layer wirings 40 is formed using, for example, a multilayer film constituted by a titanium nitride film 41 and a tungsten film 42. A width of each of the upper-layer wirings 40 (a width in a cross-section in a perpendicular direction to the first direction) is, for example, about 20 nm, and a thickness thereof is, for example, about 60 nm. In each upper-layer wiring 40, a film thickness of the titanium nitride film 41 is, for example, about 10 nm, and a film thickness of the tungsten film 42 is, for example, about 50 nm. Each of the upper-layer wirings 40 is connected to the contact plug 30 and electrically connected to one of the memory cells via the contact plug 30. As shown in FIG. 1-1, the upper-layer wirings 40 extend in the first direction and are formed into stripe line-and-space patterns in the memory region when viewed from above the semiconductor substrate 10.

As shown in FIG. 2A, a plurality of lower-layer wirings 50 are buried in the lower-layer dielectric film 20. Each of the lower-layer wirings 50 is formed using, for example, a multilayer film constituted by a titanium nitride film 51 and a tungsten film 52. A width of each of the lower-layer wirings 50 (a width in a cross-section in the perpendicular direction to the first direction) is, for example, about 30 nm and a thickness thereof is, for example, about 55 nm. In each lower-layer wiring 50, a film thickness of the titanium nitride film 51 is, for example, about 5 nm and that of the tungsten film 52 is, for example, about 55 nm. Each of the lower-layer wirings 50 is connected to the contact plug 31 and electrically connected to one memory cell via the contact plug 31. An upper surface of each lower-layer wiring 50 is located at a lower position than that of a bottom of each upper-layer wiring 40. This can suppress the upper-layer wiring 40 from being short-circuited to the lower-layer wiring 50. As shown in FIG. 1-1, the lower-layer wirings 50 extend in the first direction similarly to the upper-layer wirings 40 and are formed into stripe line-and-space patterns in the memory region when viewed from above the semiconductor substrate 10. Furthermore, when viewed from above the semiconductor substrate 10, each of the lower-layer wirings 50 is located between the adjacent upper-layer wirings 40 and side surfaces of the lower-layer wiring 50 substantially match those of the upper-layer wirings 40 present on both sides of the lower-layer wiring 50, respectively. That is, when viewed from above the semiconductor substrate 10, the upper-layer wirings 40 and the lower-layer wirings 50 are alternately arranged with very few gaps therebetween.

The lower-layer wirings 50 are provided in trenches TR formed in the lower-layer dielectric film 20, respectively. When viewed from above the semiconductor substrate 10, each of the trenches TR is formed in the lower-layer dielectric film 20 so as to be located between the adjacent upper-layer wirings 40. When viewed from above the semiconductor substrate 10, inner side surfaces of each trench TR substantially match the side surfaces of the upper-layer wirings 40 present on both sides of the trench TR, respectively. As described later, each trench TR is formed between the adjacent upper-layer wirings 40 in a self-aligned manner, so that the inner side surfaces of the trench TR are formed along the side surfaces of the upper-layer wirings 40 present on the both sides of the trench TR, respectively. Accordingly, each lower-layer wiring 50 are buried in the trench TR so that the side surfaces of the lower-layer wiring 50 are along with those of the upper-layer wirings 40 present on both sides of the lower-layer wiring 50, respectively. That is, when viewed from above the semiconductor substrate 10, the upper-layer wirings 40 and the trenches TR are alternately formed with very few gaps therebetween, so that the upper-layer wirings 40 and the lower-layer wirings 50 are also alternately arranged with very few gaps therebetween.

In this way, according to the first embodiment, the upper-layer wirings 40 and the lower-layer wirings 50 are alternately arranged with very few gaps therebetween in the memory region when viewed from above the semiconductor substrate 10. In addition, the upper-layer wirings 40 and the lower-layer wirings 50 are formed on different layers, that is, upper and lower layers, respectively and formed into a two-layer wiring structure. This follows that the upper-layer wirings 40 and the lower-layer wirings 50 are excellent in high integration and appropriate for downscaling of chips while keeping a state in which the upper-layer wirings 40 are insulated from the lower-layer wirings 50.

Furthermore, as shown in FIG. 1-1, the lower-layer wirings 50 protrude farther than the upper-layer wirings 40 in the first direction on end portions thereof. That is, the lower-layer wirings 50 are formed to be longer than the upper-layer wirings 40 or to be displaced from the upper-layer wirings 40 in the first direction. With this configuration, when contact plugs (not shown) formed on an upper layer than that on which the upper-layer wirings 40 are formed are provided, the contact plugs can be made to easily contact the lower-layer wirings 50, respectively through the interlayer dielectric film 60 while keeping a state in which the contact plugs are insulated from the upper-layer wirings 40.

FIG. 2B shows the end portion (loop cut region) of the upper-layer wiring 40 in the memory region. In the loop cut region, the lower-layer wirings 50 are not formed using the end portion of the upper-layer wiring 40 as a mask in a self-aligned manner. In the loop cut region, the lower-layer wirings 50 are formed using a lithographic technique as described later. Therefore, as shown in FIG. 1-1, the lower-layer wirings 50 are formed into shapes protruding farther than the upper-layer wirings 40 in the first direction. With this configuration, in the loop cut region, the adjacent lower-layer wirings 50 can be formed without being short-circuited to each other on the end portion of the upper-layer wiring 40.

FIGS. 1-2 and 2C show the upper-layer wiring 40 and the lower-layer wiring 50 in the peripheral circuit region. Normally, a wiring layout in the peripheral circuit region is less downscaled than that in the memory region. Therefore, wirings such as the upper-layer wirings 40 and the lower-layer wirings 50 in the peripheral circuit region can be made thicker than those in the memory region and arranged with gaps. A width of each of the upper-layer wiring 40 and the lower-layer wiring 50 (a width in the cross-section in the perpendicular direction to the first direction) in the peripheral circuit region is, for example, about 100 nm. In the peripheral circuit region, each of the upper-layer wirings 40 is electrically connected to one of the semiconductor elements such as the transistors, the resistors, and the capacitors formed on the surface of the semiconductor substrate 10 via the contact plug 30. Each of the lower-layer wirings 50 is electrically connected to one of the semiconductor elements such as the transistors, the resistors, and the capacitors formed on the surface of the semiconductor substrate 10 via the contact plug 31.

The upper-layer wirings 40 and the lower-layer wirings 50 according to the first embodiment can be used as, for example, bit lines of the NAND flash EEPROM. In this case, the adjacent bit lines are kept insulated from each other and, when viewed from above the surface of the semiconductor substrate 10, the adjacent bit lines are arranged compactly without any gap. Needless to mention, the upper-layer wirings 40 and the lower-layer wirings 50 can be used as, for example, other wirings of the NAND flash EEPROM.

Next, a manufacturing method of the semiconductor memory device according to the first embodiment is described.

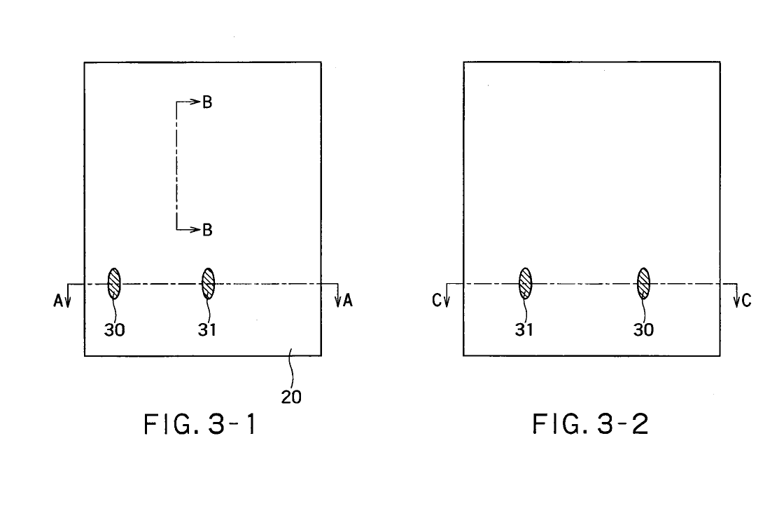

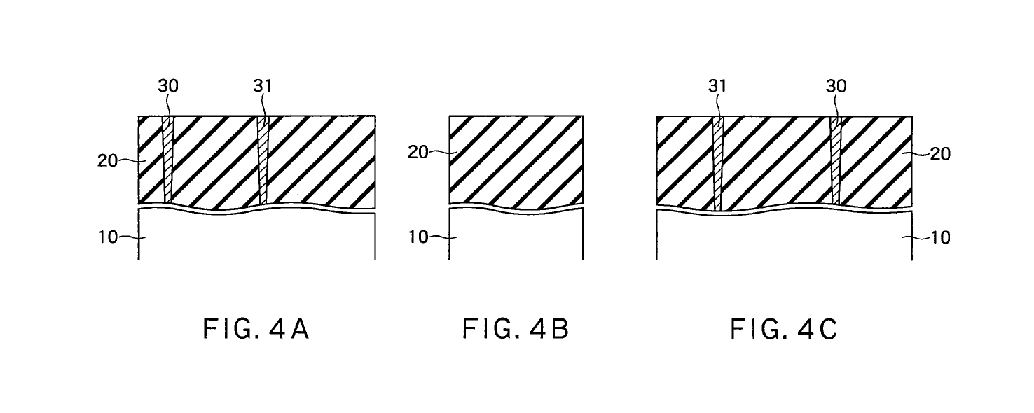

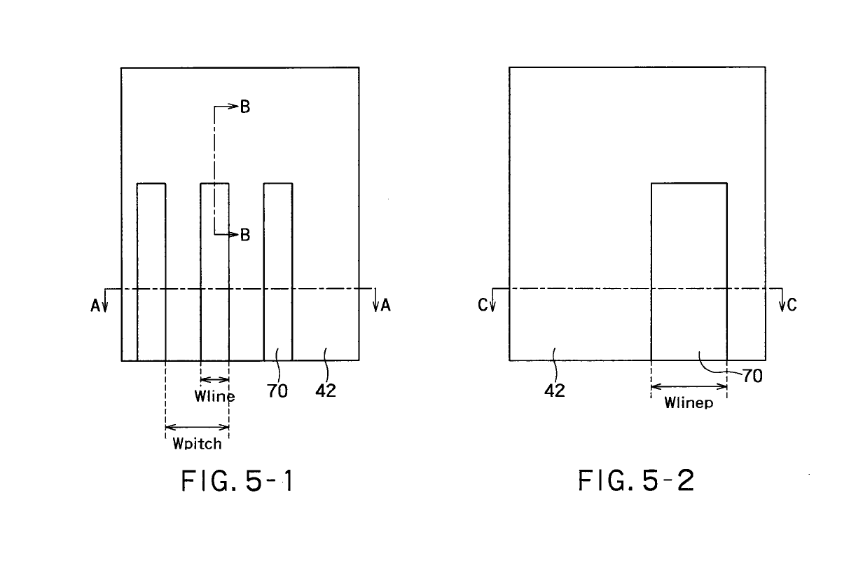

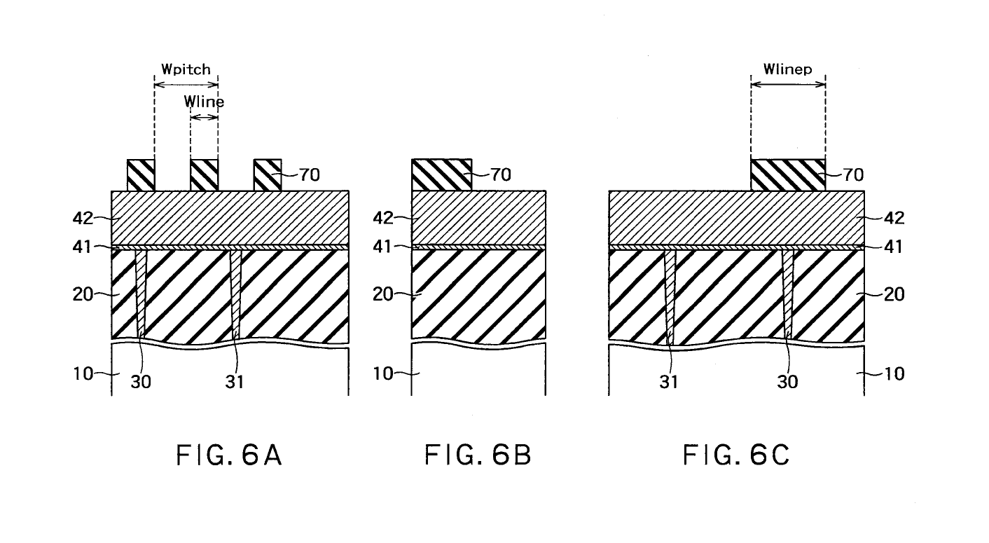

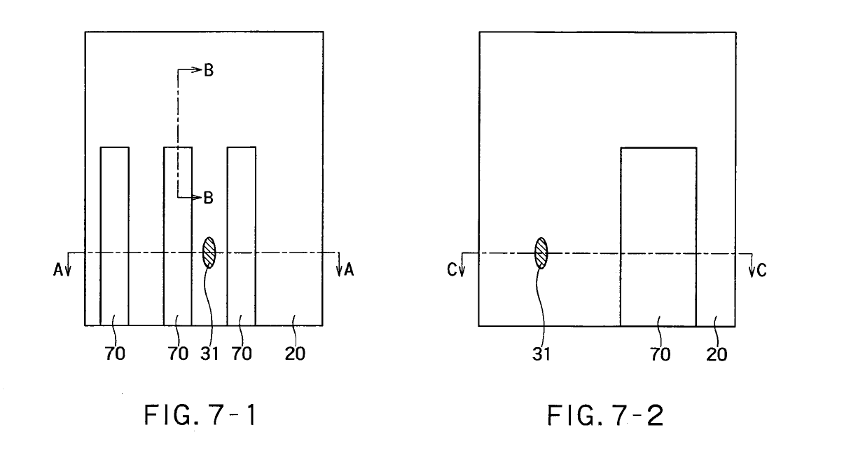

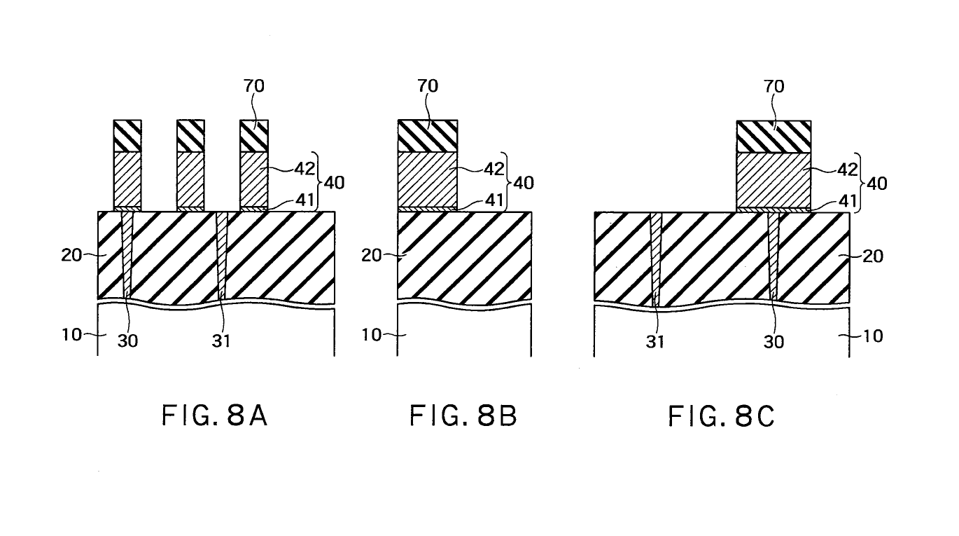

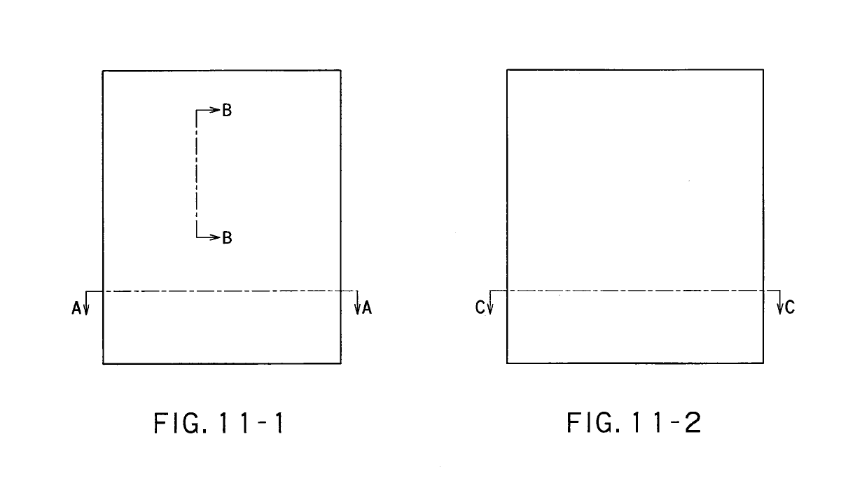

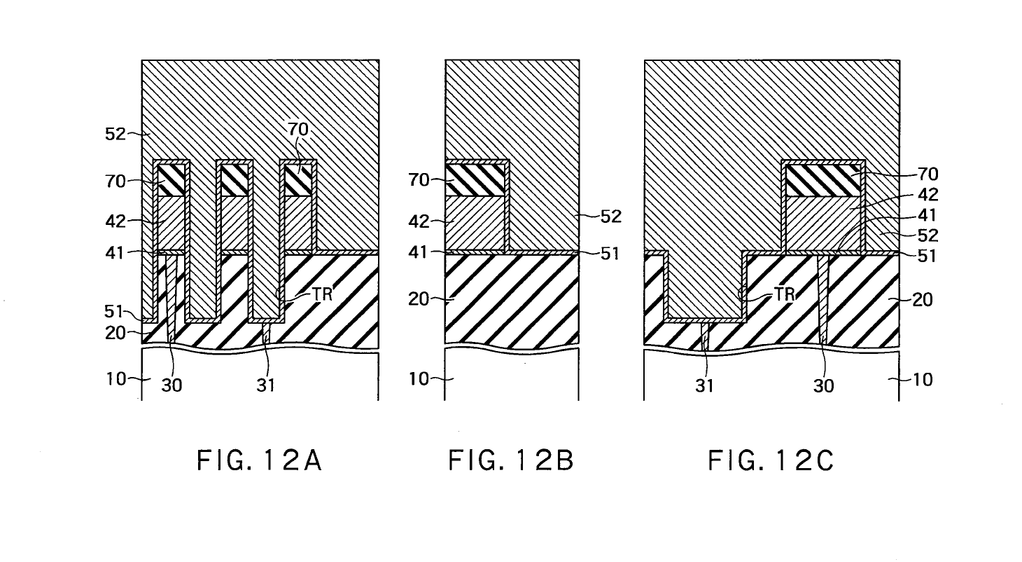

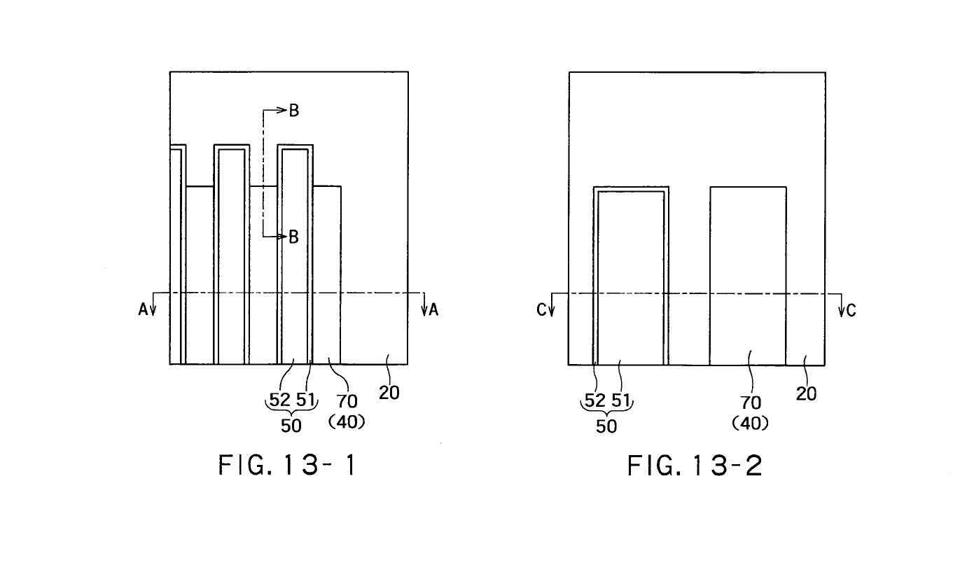

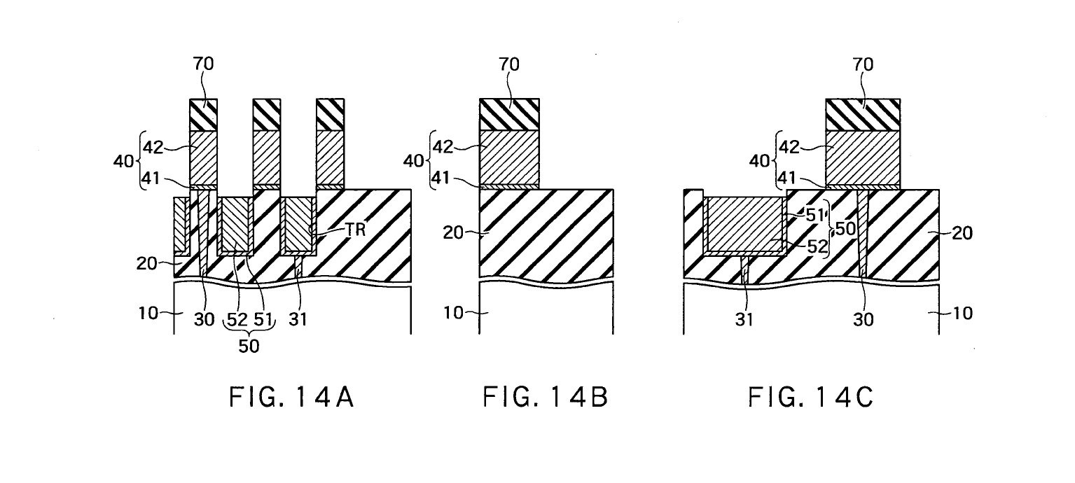

FIGS. 3-1 to 14C are cross-sectional views showing the manufacturing method of the memory device according to the first embodiment. FIGS. 3-1, 5-1, 7-1, 9-1, 11-1, and 13-1 correspond to FIG. 1-1 and FIGS. 3-2, 5-2, 7-2, 9-2, 11-2, and 13-2 correspond to FIG. 1-2. FIGS. 4A, 6A, 8A, 10A, 12A, and 14A correspond to FIG. 2A, FIGS. 4B, 6B, 8B, 10B, 12B, and 14B correspond to FIG. 2B and FIGS. 4C, 6C, 8C, 10C, 12C, and 14C correspond to FIG. 2C.

First, the semiconductor elements such as the memory cells, the transistors, the resistors, and the capacitors are formed on the surface of the semiconductor substrate 10. Next, the lower-layer insulating film 20 covering the semiconductor elements is formed. The lower-layer insulating film 20 is formed using, for example, a silicon oxide film. As shown in FIGS. 3-1 to 4C, the contact plugs 30 and 31 are formed in the lower-layer insulating film 20. The contact plugs 30 and 31 are formed using, for example, metal such as tungsten. Each of the contact plugs 30 is used to electrically connect one of the upper-layer wirings 40 to any one of the semiconductor elements. Each of the contact plugs 31 is used to electrically connect one of the lower-layer wirings 50 to any one of the semiconductor elements.

Next, as shown in FIGS. 5-1 to 6C, the metal films 41 and 42 (first metal films) are formed on a surface of the lower-layer insulating film 20 as a material of the upper-layer wirings 40. The metal film 41 is the titanium nitride film having the thickness of, for example, about 10 nm. The metal film 42 is the tungsten film having the thickness of, for example, about 50 nm. The upper-layer wirings 40 are formed using the multilayer film of such metal films 41 and 42.

Alternatively, contact holes can be formed in advance at positions of forming the contact plugs 30 and 31 in the lower-layer insulating film 20, and materials of the metal films 41 and 42 can be filled in those contact holes, respectively at a time of depositing the material of the upper-layer wirings 40. This makes it possible to execute the formation of the contact plugs 30 and 31 and the deposition of the material of the upper-layer wirings 40 either simultaneously or continuously. This can shorten manufacturing processes of the memory device.

Next, a hard mask 70 is formed on the metal film 42 as a first mask. A material of the hard mask 70 is formed using a silicon nitride film having a thickness of, for example, about 20 nm. The material of the hard mask 70 is processed using the lithographic technique and a dry etching method (an RIE (Reactive Ion Etching) method, a CDE (Chemical Dry Etching) method or the like, for example). The hard mask 70 is thereby formed into planar patterns (line-and-space patterns) of the upper-layer wirings 40 as shown in FIGS. 5-1 to 6C. For example, a pitch width Wpitch of the line-and-space patterns of the hard mask 70 is about 50 nm, and a line width Wline of each hard mask 70 is about 20 nm. Furthermore, a line width Wlinep of each hard mask 70 in the peripheral circuit region is, for example, about 100 nm.

As shown in FIGS. 7-1 to 8C, the metal films 41 and 42 are processed by the dry etching method using the hard masks 70 as masks. The plural upper-layer wirings 40 are thereby formed into the line-and-space patterns.

As shown in FIGS. 9-1 to 10C, a photoresist PR1 is formed using the lithographic technique so that regions of forming the lower-layer wirings 50 can be exposed and that other regions can be covered. Next, using the photoresist PR1 and the hard masks 70 (and/or the metal films 41 and 42) as masks, the lower-layer insulating film 20 is etched by the dry etching method. The trenches TR are thereby formed at positions of forming the lower-layer wirings 50, respectively in a self-aligned manner. A depth of each trench TR is, for example, about 65 nm from the surface of the lower-layer insulating film 20. In the memory region, the trenches TR are formed in a self-aligned manner using the hard masks 70 and/or the metal films 41 and 42 as the masks. That is, each of the trenches TR is formed between the adjacent upper-layer wirings 40 in a self-aligned manner. Therefore, when viewed from above the surface of the semiconductor substrate 10, the inner side surfaces of each trench TR are formed along the side surfaces of the upper-layer wirings 40 present on the both sides of the trench TR, respectively. For example, an inner side surface Ftr1 of the trench TR is flush with a side surface F40_1 of the upper layer wiring 40. Likewise, inner side surfaces Ftr2 to Ftr4 of the trenches TR are flush with side surfaces F40_2 to F40_4 of the upper layer wirings 40, respectively.

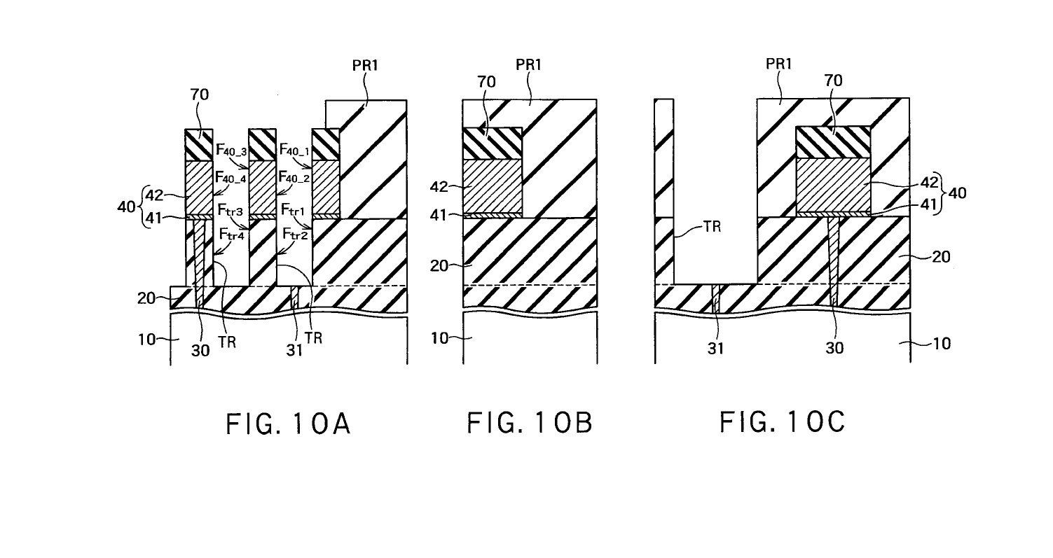

Furthermore, as shown in FIG. 10B, the end portion of each upper-layer wiring 40 is covered with the photoresist PR1.

The end portion of the upper-layer wiring 40 corresponds to the loop cut region of the lower-layer wiring 50. When the end portion of each upper-layer wiring 40 is exposed, the trenches TR are formed into loop shapes so as to surround the end portions of the upper layer wirings 40. In this case, when forming the lower-layer wirings 50, the material of the lower-layer wirings 50 is also formed into loop shapes so as to surround the end portions of the upper-layer wirings 40. Therefore, the lower-layer wirings 50 adjacent in an orthogonal direction to the first direction are short-circuited to each other. To suppress such short-circuit between the lower-layer wirings 50, the end portion of each upper-layer wiring 40 is covered with the photoresist PR1. That is, the loop cut region of each lower-layer wiring 50 is covered with the photoresist PR1. With this configuration, the trenches TR are not formed around the end portion of each upper-layer wiring 40 and the material of the lower-layer wirings 50 is not deposited around the end portion of the upper-layer wiring 40. That is, the trenches TR and the lower-layer wirings 50 are not formed into the loop shapes. Therefore, it is possible to suppress the adjacent lower-layer wirings 50 from being short-circuited to each other.

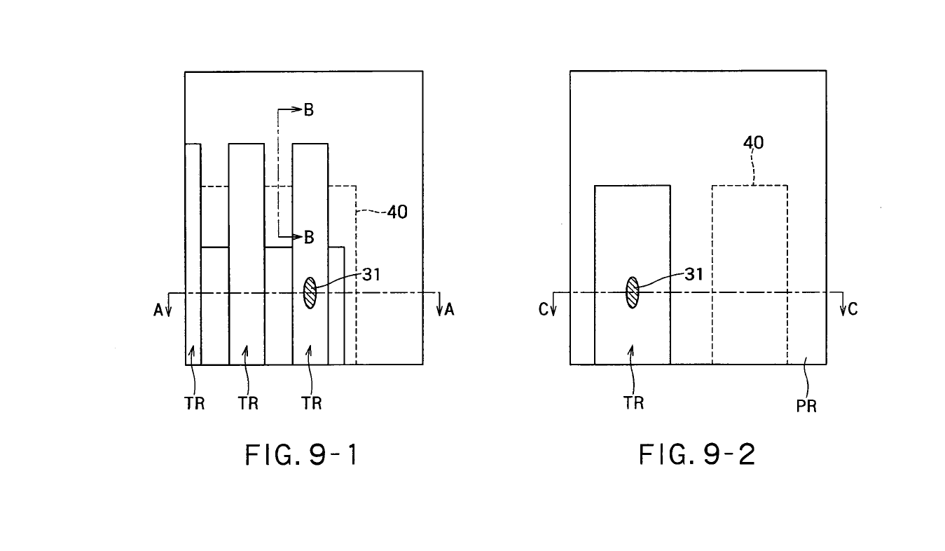

Meanwhile, as shown in FIG. 9-1, on end portions of the regions of forming the lower-layer wirings 50, the trenches TR are formed to be longer than the upper-layer wirings 40 or displaced from the upper-layer wirings 40 in the first direction. That is, on the end portions of the regions of forming the lower-layer wirings 50, the trenches TR protrude farther than the upper-layer wirings 40 in the first direction. The lower-layer wirings 50 protruding farther than the upper-layer wirings 40 in the first direction can be thereby formed on the end portions.

As shown in FIGS. 9-2 and 10C, the trenches TR can be formed even in the peripheral circuit region as long as the trenches TR do not overlap the upper-layer wirings 40. The lower-layer wirings 50 are formed in these trenches TR, respectively.

As shown in FIGS. 10A to 10C, an etching stopper film can be formed in advance at a predetermined depth in the lower-layer insulating film 20 so as to determine positions of bottoms of the trenches TR. The predetermined depth is, for example, at a dashed position shown in FIGS. 10A to 10C. The etching stopper film is a material such as a silicon nitride film lower in etching rate than the lower-layer insulating film 20.

After removing the photoresist PR1, the material of the lower-layer wirings 50 is deposited as shown in FIGS. 11-1 to 12C. As the material of the lower-layer wirings 50, the metal films 51 and 52 (second metal films) are formed. The metal film 51 is the titanium nitride film having the thickness of, for example, about 5 nm. The metal film 52 is the tungsten film having the thickness of, for example, about 250 nm. The lower-layer wirings 50 are formed by using the multilayer film constituted by these metal films 51 and 52. The metal films 51 and 52 are thereby filled in each of the trenches TR.

Using a CMP (Chemical Mechanical Polishing) method, the metal films 51 and 52 are polished until the hard masks 70 are exposed. The metal films 51 and 52 are thereby planarized. The planarization of the metal films 51 and 52 makes heights of upper surfaces of the lower-layer wirings 50 substantially uniform. This contributes to suppressing each upper-layer wiring 40 from being short-circuited to the lower-layer wiring 50. Furthermore, by making the heights of the upper surfaces of the lower-layer wirings 50 substantially uniform, resistances of the lower-layer wirings 50 are made substantially uniform and the inter-wiring capacity between the lower-layer wirings 50 or that between the upper-layer wirings 40 and the lower-layer wirings 50 is made uniform. It is thereby possible to make RC delays in the upper-layer wirings 40 and those in the lower-layer wirings 50 substantially constant, respectively.

At a time of the planarization by the CMP method, the hard masks 70 function as a CMP stopper. However, the metal film 51 can be used as the CMP stopper. In the latter case, the metal film 52 is polished until the metal film 51 is exposed.

With this method, it is also possible to planarize the metal films 51 and 52.

Furthermore, when a surface of the metal film 52 is sufficiently planar at a time of forming the metal films 51 and 52, even a planarization process by the CMP method itself can be omitted. In this case, the manufacturing processes of the memory device can be shortened.

Next, using the hard masks 70 and/or the upper-layer wirings 40 (metal films 41 and 42) as masks, the metal films 51 and 52 are etched back by the dry etching method. The lower-layer wirings 50 are thereby formed in the respective trenches TR as shown in FIGS. 13-1 to 14C.

At this time, the lower-layer wirings 50 are etched back down to positions lower than an upper surface of the lower-layer insulating film 20 (bottoms of the upper-layer wirings 40). For example, the upper surfaces of the lower-layer wirings 50 are located at positions lower by about 10 nm than the upper surface of the lower-layer insulating film 20 (bottoms of the upper-layer wirings 40) (located at positions closer to the semiconductor substrate 10). The lower-layer wirings 50 are thereby electrically separated from the upper-layer wirings 40.

The lower-layer wirings 50 are buried in a lower part of the respective trenches TR formed in a self-aligned manner using the hard masks 70 or the upper-layer wirings 40 as the masks. Therefore, when viewed from above the semiconductor substrate 10, each of the lower-layer wirings 50 is located between the adjacent upper-layer wirings 40 similarly to each of the trenches TR. Furthermore, when viewed from above the semiconductor substrate 10, the side surfaces of each of the lower-layer wirings 50 are along and substantially match those of the upper-layer wirings 40 present on the both sides of the lower-layer wiring 50, respectively.

After removing the hard masks 70, the interlayer dielectric film 60 is deposited so as to fill gaps between the adjacent upper-layer wirings 40. The interlayer dielectric film 60 is formed using a silicon oxide film having a thickness of, for example, about 150 nm. A structure shown in FIGS. 1-1 to 2C is thereby obtained. Thereafter, upper-layer wiring layers, contact plugs, and the like are further formed as necessary, thereby completing the memory device according to the first embodiment.

As described above, in the manufacturing method of the memory device according to the first embodiment, each of the trenches TR is formed between the adjacent upper-layer wirings 40 in a self-aligned manner by etching the lower-layer insulating film 20 using the hard masks 70 or the upper-layer wirings 40 as the masks. By filling the material of the lower-layer wirings 50 in the trenches TR, each lower-layer wiring 50 is formed in each trench TR in a self-aligned manner. In the memory region, the upper-layer wirings 40 and the lower-layer wirings 50 are thereby alternately arranged with very few gaps therebetween when viewed from above the semiconductor substrate 10. The upper surface of each lower-layer wiring 50 is located at the lower position than that of the bottom of each upper-layer wiring 40. With this configuration, with the manufacturing method according to the first embodiment, it is possible to manufacture the memory device higher in integration than the conventional memory device while keeping the state in which the upper-layer wirings 40 are insulated from the lower-layer wirings 50. As a result, it is possible to manufacture the memory device high in reliability and small in chip size.

Furthermore, the lower-layer wirings 50 are formed to protrude farther than the upper-layer wirings 40 in the first direction on the end portions. With this configuration, when contact plugs (not shown) formed on the upper layer than that on which the upper-layer wirings 40 are formed are provided, the contact plugs can be made to easily contact the lower-layer wirings 50, respectively through the interlayer dielectric film 60 while keeping the state in which the contact plugs are insulated from the upper-layer wirings 40.

Further, by making the heights of the upper surfaces of the lower-layer wirings 50 substantially uniform, the resistances of the lower-layer wirings 50 are made substantially uniform and the inter-wiring capacity between the lower-layer wirings 50 or that between the upper-layer wirings 40 and the lower-layer wirings 50 is made uniform. It is thereby possible to make the RC delays in the upper-layer wirings 40 substantially equal and make the RC delays in the lower-layer wirings 50 substantially equal. Further, by adjusting an inter-wiring distance between each of the upper-layer wirings 40 and the lower-layer wiring 50, the wiring width, and the wiring height, the RC delays in the lower-layer wirings 50 can be made substantially equal to those in the upper-layer wirings 40. As a result, the upper-layer wirings 40 and the lower-layer wirings 50 can be used as wirings (bit lines, for example) identical in function.

### First Modification of First Embodiment

In the first embodiment, the material of each of the upper-layer wirings 40 and the lower-layer wirings 50 is formed using the multilayer metal film constituted by tungsten and titanium nitride. However, each of the upper-layer wirings 40 and the lower-layer wirings 50 can be formed using a single metal layer. Even if each of the upper-layer wirings 40 and the lower-layer wirings 50 is formed using the single metal layer, effects of the first embodiment are not lost.

Furthermore, the upper-layer wirings 40 and the lower-layer wirings 50 can be formed using different metal materials, respectively. For example, the upper-layer wirings 40 can be formed using tungsten whereas the lower-layer wirings 50 can be formed using copper. In this manner, even if the upper-layer wirings 40 and the lower-layer wirings 50 are formed using the different metal materials from each other, the effects of the first embodiment are not lost.

### Second Modification of First Embodiment

In the first embodiment, the lower-layer insulating film 20 and the interlayer dielectric film 60 are both formed using the silicon oxide film. However, the lower-layer insulating film 20 and the interlayer dielectric film 60 can be formed using a so-called low-dielectric film (Low-k film) having a dielectric constant equal to or lower than 3.7 in place of the silicon oxide film having a dielectric constant of about 4.0 to 4.5. By using the Low-k film for the lower-layer insulating film 20 and the interlayer dielectric film 60, the inter-wiring capacity can be reduced. For example, the lower-layer insulating film 20 and the interlayer dielectric film 60 can be formed using a fluorinated silicon oxide film (FSG), a carbon-based silicon oxide film (SiOC), an inorganic film containing hydrogen silsesquioxane (HSQ), methyl silsesquioxane (MSQ) or the like, an organic film containing polyarylether, benzocyclobutene, polytetrafluoroethylene or the like, a porous silica film or the like. In this manner, the lower-layer insulating film 20 and the interlayer dielectric film 60 can be both formed using the Low-k film.

### Third Modification of First Embodiment

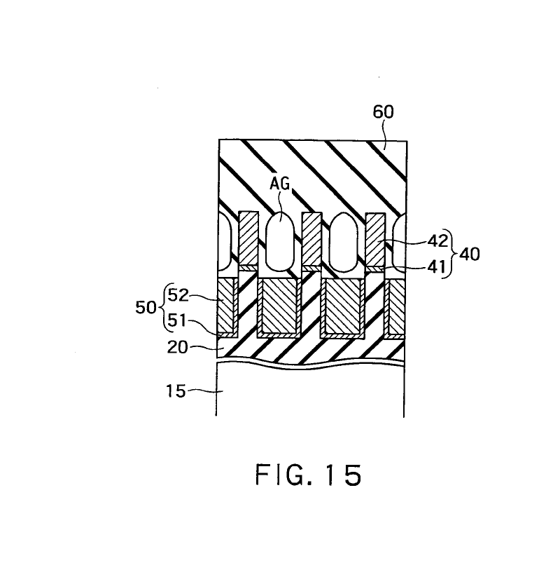

FIG. 15 is a cross-sectional view showing air gaps AG each formed in the interlayer dielectric film 60 between the upper-layer wirings 40. In this manner, each of the air gaps AG can be formed in the interlayer dielectric film 60 between the adjacent upper-layer wirings 40. Each air gap AG reduces the inter-wiring capacity between the adjacent upper-layer wirings 40. Therefore, the air gaps AG can reduce the RC delays in the upper-layer wirings 40.

When the air gaps AG reduce the RC delays in the upper-layer wirings 40, it is considered to lower resistances of the lower-layer wirings 50 so as to make the RC delays in the upper-layer wirings 40 equal to those in the lower-layer wirings 50. To lower the resistances of the lower-layer wirings 50, a cross-sectional area of each lower-layer wiring 50 is made larger than that of each upper-layer wiring 40. For example, the width of each lower-layer wiring 50 (the width the cross-section orthogonal to the first direction) is made larger than that of each upper-layer wiring 40. That is, the trenches TR are formed to be wider than the upper-layer wirings 40. This can make the RC delays in the upper-layer wirings 40 and those in the lower-layer wirings 50 substantially equal while reducing the RC delays in both the upper-layer wirings 40 and the lower-layer wirings 50.

Needless to mention, the height or depth (thickness) of each of the lower-layer wirings 50 can be made larger. However, in this case, it is necessary to pay attention to preventing each of the lower-layer wirings 50 from being short-circuited to each of the upper-layer wirings 40.

It suffices to form the air gaps AG by depositing a film having inferior coverage (film having inferior embeddability) using plasma CVD (Chemical Vapor Deposition) when filling the interlayer dielectric film 60 between the adjacent upper-layer wirings 40.

### Second Embodiment

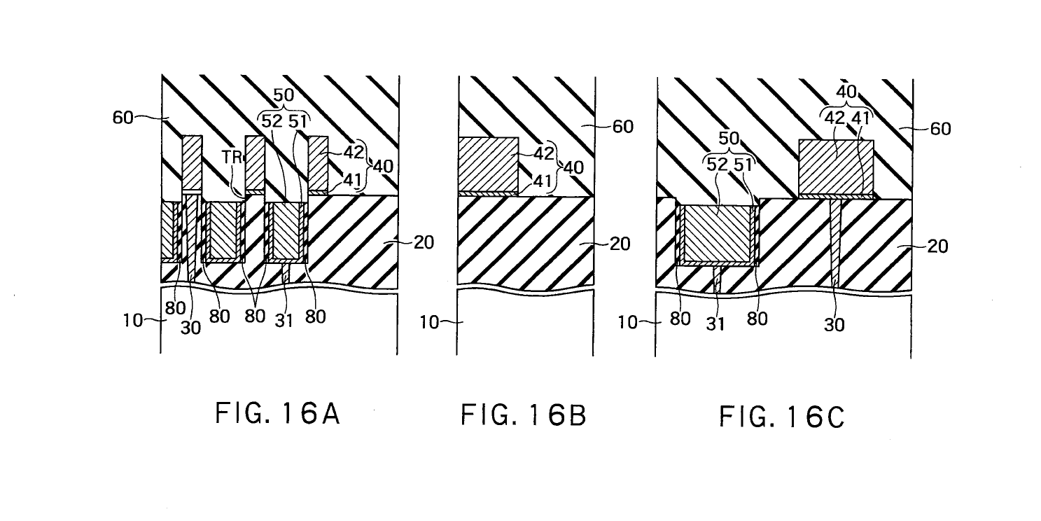

FIGS. 16A to 16C are cross-sectional views showing an example of a configuration of a memory device according to the second embodiment. The plan view of the memory device according to the second embodiment is not shown herein because the plan view can be easily understood with reference to FIGS. 1-1 and 1-2.

In the second embodiment, sidewall insulating films 80 are formed on the inner side surfaces of each trench TR, respectively. Each of the lower-layer wirings 50 is provided in the trench TR via the sidewall insulating films 80. Even if a distance between the contact plug 30 and one of the inner side surfaces of the trench TR is short, each of the sidewall insulating films 80 can suppress the lower-layer wiring 50 from being short-circuited to the contact plug 30. That is, even if a thickness of the lower-layer insulating film 20 (a film thickness in the orthogonal direction (a second direction) to the first direction) between the contact plug 30 and one of the inner side surfaces of the trench TR is small, the sidewall insulating film 80 reinforces the lower-layer insulating film 20 and can, therefore, suppress the lower-layer wiring 50 from being short-circuited to the contact plug 30.

As described later, even if misalignment occurs to some extent in a lithographic process at a time of forming the hard masks 70, the sidewall insulating films 80 can suppress each lower-layer wiring 50 from being short-circuited to the contact plug 30.

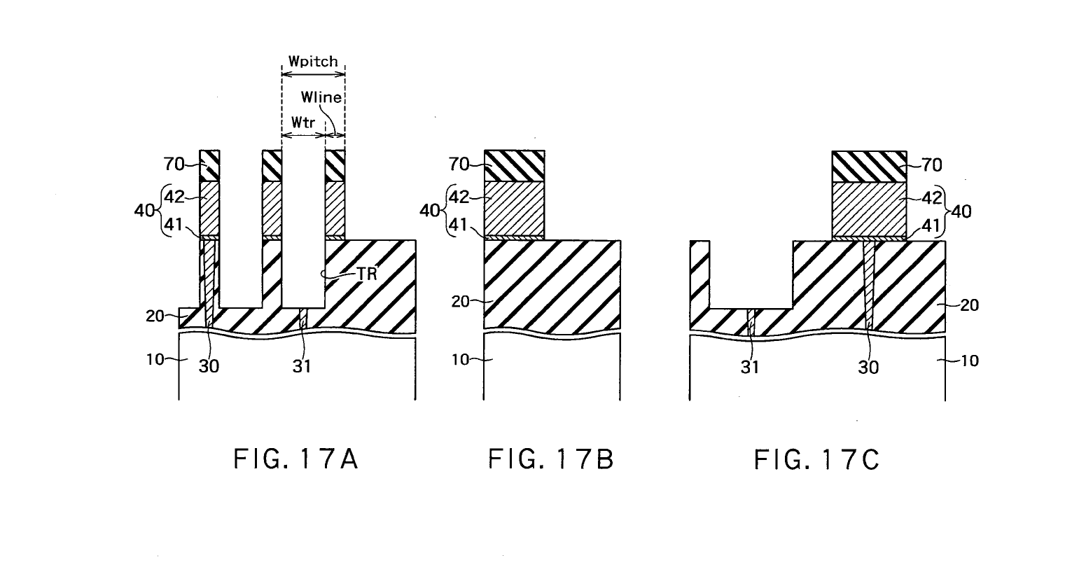

FIGS. 17A to 21C are cross-sectional views showing a manufacturing method of the memory device according to the second embodiment. FIGS. 17A to 21A correspond to FIG. 16A, FIGS. 17B to 21B correspond to FIG. 16B, and FIGS. 17C to 21C correspond to FIG. 16C.

First, the trenches TR are formed similarly to the first embodiment after performing processes shown in FIGS. 3-1 to 10C. A cross-sectional structure shown in FIGS. 17A to 17C is thereby obtained. Specific examples of the width and the height of each of the upper-layer wirings 40 can be made equal to those of each of the upper-layer wirings 40 in the first embodiment. The pitch Wpitch of the upper-layer wirings 40 in the memory region is, for example, about 70 nm. The width Wline of each upper-layer wiring 40 is, for example, about 20 nm. A width Wtr of each trench TR is, for example, about 50 nm. In the second embodiment, because the sidewall insulating films 80 are formed on the inner side surfaces of each trench TR, respectively, it is necessary to make the width Wtr of the trench TR larger than a desired width of each lower-layer wiring 50 in light of widths of the sidewall insulating films 80 so as to make the RC delays in the upper-layer wirings 40 equal to those in the lower-layer wirings 50. When assuming that the width of each lower-layer wiring 50 is W50 and that of each sidewall insulating film 80 is W80, the width Wtr of each trench TR is W50+2×W80. For example, when assuming that the width W50 of the lower-layer wiring 50 is 30 nm and that the width W80 of the sidewall insulating film 80 is 10 nm, the width Wtr of the trench TR is 50 nm.

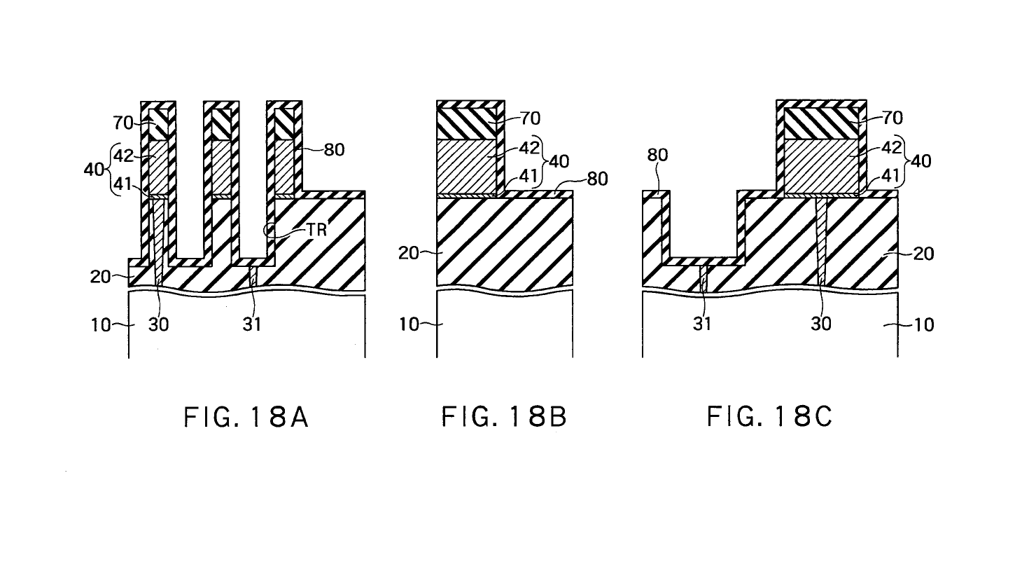

Next, as shown in FIGS. 18A to 18C, the sidewall insulating film 80 is deposited on an inner surface of each trench TR, side surfaces of each upper-layer wiring 40, and the like. The sidewall insulating film 80 is a silicon oxide film having a film thickness of, for example, about 10 nm.

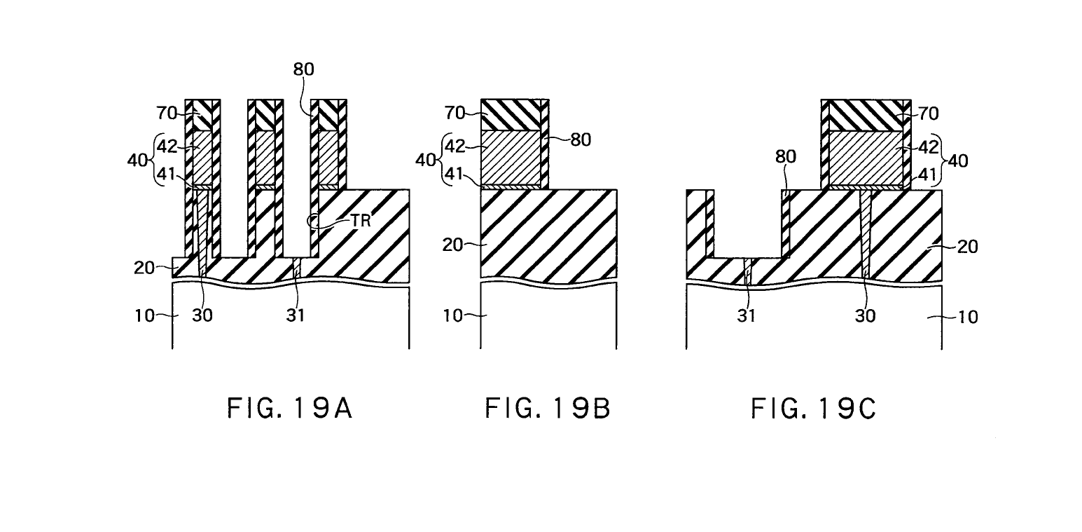

Next, as shown in FIGS. 19A to 19C, the sidewall insulating film 80 is etched back by using the dry etching method. The sidewall insulating film 80 present on the bottom of each trench TR is thereby removed while leaving the sidewall insulating films 80 formed on the inner side surfaces of the trenches TR, respectively. Upper surfaces of the contact plugs 31 are thereby exposed. At this time, the sidewall insulating film 80 on each hard mask 70 is also removed.

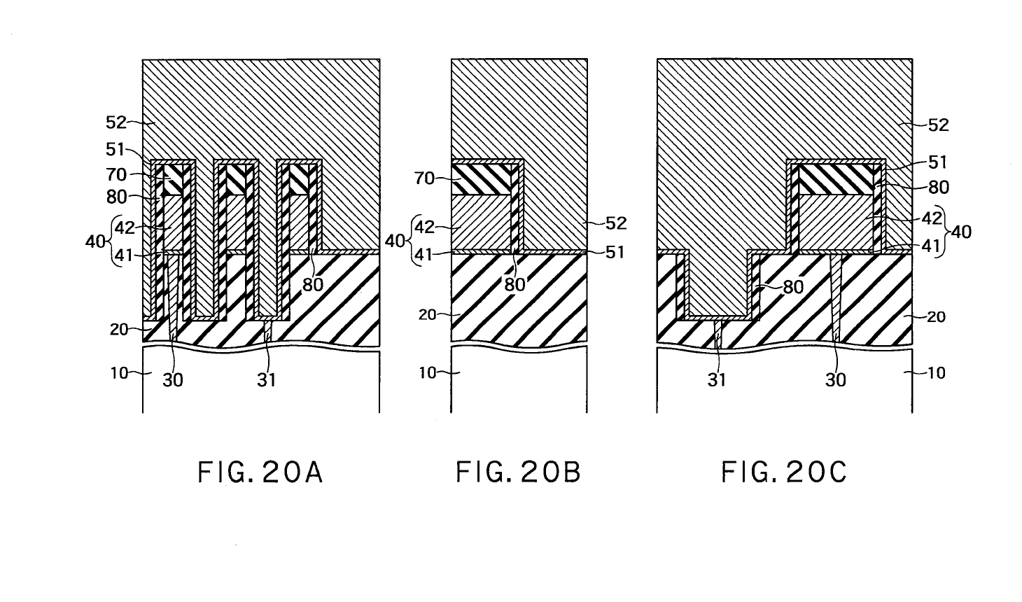

Next, as shown in FIGS. 20A to 20C, the metal films 51 and 52 are deposited as the material of the lower-layer wirings 50. The metal films 51 and 52 are thereby filled in each trench TR. The metal film 51 is formed using the titanium nitride film having the thickness of, for example, about 5 nm. The metal film 52 is formed using the tungsten film having the thickness of, for example, about 250 nm.

Next, using the CMP method, the metal films 51 and 52 are polished until the hard masks 70 are exposed. The metal films 51 and 52 are thereby planarized. The planarization of the metal films 51 and 52 makes the heights of upper surfaces of the lower-layer wirings 50 substantially uniform. This contributes to suppressing each upper-layer wiring 40 from being short-circuited to the lower-layer wiring 50 as already described above.

In the second embodiment, similarly to the first embodiment, the metal film 51 can be used as the CMP stopper. When the surface of the metal film 52 is sufficiently planar at the time of forming the metal films 51 and 52, even the planarization process by the CMP method itself can be omitted.

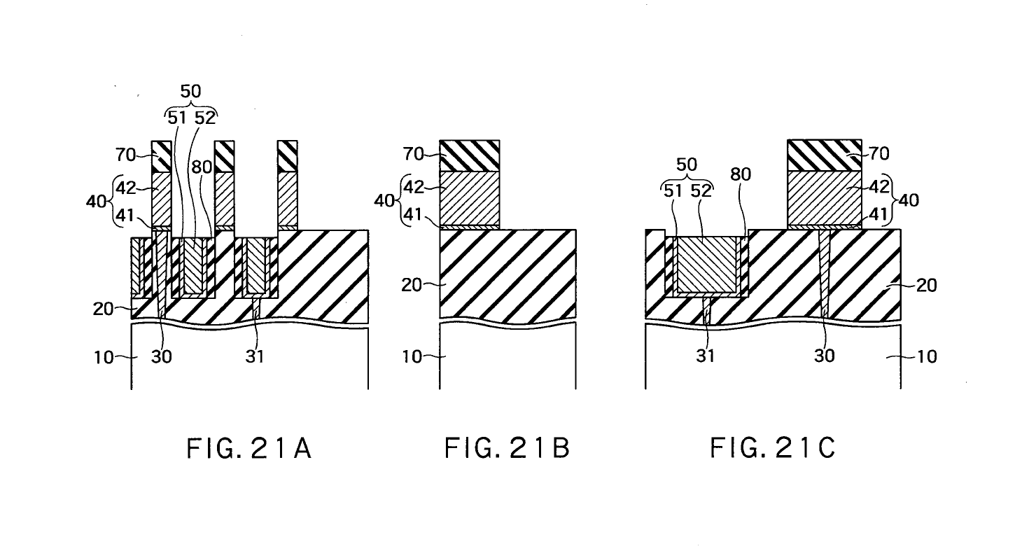

Next, using the hard masks 70 and/or the upper-layer wirings 40 (metal films 41 and 42) as masks, the metal films 51 and 52 and the sidewall insulating films 80 are etched back by the dry etching method. Each lower-layer wiring 50 and the sidewall insulating films 80 are thereby formed in each trench TR as shown in FIGS. 21A to 21C.

At this time, the lower-layer wirings 50 are etched back down to the positions lower than the upper surface of the lower-layer insulating film 20 (the bottoms of the upper-layer wirings 40). For example, the upper surfaces of the lower-layer wirings 50 are located at the positions lower by about 10 nm than the upper surface of the lower-layer insulating film 20 (the bottoms of the upper-layer wirings 40) (located at the positions closer to the semiconductor substrate 10). The lower-layer wirings 50 are thereby electrically separated from the upper-layer wirings 40.

Similarly, the sidewall insulating films 80 are etched back down to the same positions as those of the lower-layer wirings 50. The sidewall insulating films 80 are thereby left on the side surfaces of each lower-layer wiring 50, respectively. That is, each of the sidewall insulating films 80 is left between the inner side surface of each trench TR and each lower-layer wiring 50.

Next, after removing the hard masks 70, the interlayer dielectric film 60 is deposited so as to fill the gaps between the adjacent upper-layer wirings 40. The interlayer dielectric film 60 is formed using the silicon oxide film having the thickness of, for example, about 150 nm. A structure shown in FIGS. 16A to 16C is thereby obtained. Thereafter, the upper-layer wiring layers, the contact plugs, and the like are further formed as necessary, thereby completing the memory device according to the second embodiment.

In the second embodiment, the sidewall insulating film 80 interposes between each lower-layer wiring 50 and the inner side surface of each trench TR. Therefore, when viewed from above the semiconductor substrate 10, the side surfaces of each lower-layer wiring 50 do not match those of the upper-layer wirings 40 present on the both sides of the lower-layer wiring 50, respectively but side surfaces of the sidewall insulating films 80 substantially match those of the upper-layer wirings 40.

However, the trenches TR are formed in a self-aligned manner using the hard masks 70 or the upper-layer wirings 40 as the masks, and the lower-layer wirings 50 as well as the sidewall insulating films 80 are formed in the trenches TR in a self-aligned manner. Therefore, similarly to the first embodiment, when viewed from above the semiconductor substrate 10, the inner side surfaces of each trench TR substantially match the side surfaces of the upper-layer wirings 40 present on the both sides of the trench TR, respectively. In the memory region, when viewed from above the semiconductor substrate 10, the upper-layer wirings 40 and the lower-layer wirings 50 are thereby alternately arranged with a gap corresponding to the film thickness of each sidewall insulating film 80 between each upper-layer wiring 40 and each lower-layer wiring 50. Furthermore, the upper surface of each lower-layer wiring 50 is at the lower position than that of the bottom of each upper-layer wiring 40. With the manufacturing method according to the second embodiment, it is thereby possible to further ensure the state in which each upper-layer wiring 40 is insulated from each lower-layer wiring 50 and to manufacture the memory device higher in integration than the conventional memory device.

### (Effect on Misalignment)

When misalignment occurs in the lithographic process at a time of forming the hard masks 70, short-circuit possibly occurs between the lower-layer wirings 50 and the contact plugs 30. However, according to the second embodiment, it is possible to effectively suppress each of the lower-layer wirings 50 from being short-circuited to one of the contact plugs 30 because the sidewall insulating film 80 interposes between the lower-layer wiring 50 and the contact plug 30.

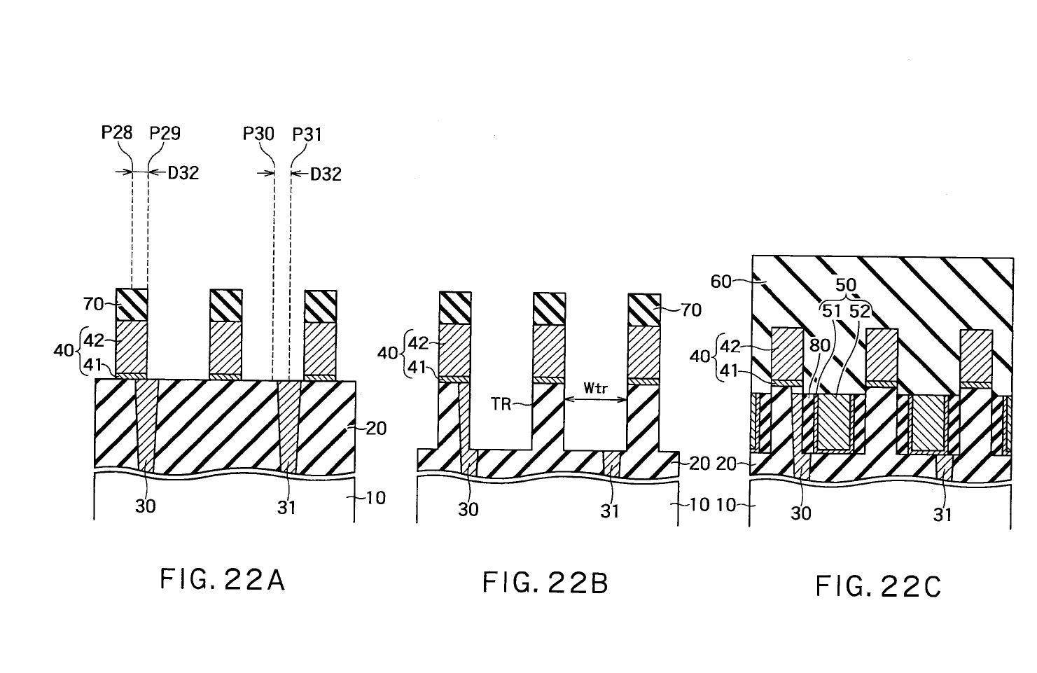

FIGS. 22A to 22C are cross-sectional views showing a specific example of the manufacturing method in a case where the misalignment occurs in the lithographic process at the time of forming the hard masks 70. In FIG. 22A, the hard masks 70 and the upper-layer wirings 40 are formed to be displaced with respect to the contact plugs 30. It is assumed herein that the misalignment is not so large that each upper-layer wiring 40 is unable to contact the contact plug 30. It is also assumed that the misalignment is not so large that each upper-layer wiring 40 contacts the contact plug 31. A distance between the adjacent upper-layer wirings 40 (an opening width of each trench TR) can be made longer so as to suppress the contact between each upper-layer wiring 40 and the contact plug 31.

A position P28 indicates a central position of each upper-layer wiring 40 and a position P29 indicates a central position of each contact plug 30. It is preferable in a normal situation that the position P28 matches the position P29. However, the misalignment causes the positions P28 and P29 to be displaced with respect to each other by a distance D32. Therefore, each contact plug 30 protrudes outward of the bottom of the upper-layer wiring 40.

A position P30 indicates a central position between the adjacent upper-layer wirings 40 (a central position of each trench TR). A position P31 indicates a central position of each contact plug 31. The position P30 is displaced with respect to the position P31 by the distance D32. Therefore, each upper-layer wiring 40 is formed at a closer position to the contact plug 31. However, because the upper-layer wirings 40 are formed with a long distance, each upper-layer wiring 40 does not protrude to the upper surface of the contact plug 31. Therefore, the upper-layer wiring 40 is not short-circuited to the contact plug 31.

Next, using the hard masks 70 and/or the upper-layer wirings 40 as masks, the lower-layer insulating film 20 is etched and the trenches TR are formed as shown in FIG. 22B. At this time, because each contact plug 30 protrudes outward of the bottom of the upper-layer wiring 40, the contact plug 30 is in a state of being exposed to the inner side surface and the bottom of one trench TR.

Because each upper-layer wiring 40 does not protrude to the upper surface of the contact plug 31, each contact plug 31 is removed by as much as a depth corresponding to a position of the bottom of each trench TR.

In a case of filling the material of the lower-layer wirings 50 in each trench TR without forming the sidewall insulating films 80, each lower-layer wiring 50 contacts the contact plug 30 on the inner side surface and the bottom of the trench TR. This causes the lower-layer wiring 50 to be short-circuited to the upper-layer wiring 40 via the contact plug 30.

On the other hand, according to the second embodiment, each sidewall insulating film 80 is provided between one inner side surface of each trench TR and one side surface of each lower-layer wiring 50 as shown in FIG. 22C. Furthermore, the sidewall insulating film 80 also covers an end portion of the bottom of each trench TR. Therefore, the sidewall insulating film 80 can suppress each lower-layer wiring 50 from being short-circuited to the contact plug 30.

Furthermore, in the second embodiment, the width Wtr of each trench TR is formed larger in light of the film thickness of the sidewall insulating films 80. Therefore, the probability that each upper-layer wiring 40 is arranged on the contact plug 31 is lower. The contact plug 31 is thereby removed by as much as the depth corresponding to the position of the bottom of each trench TR, so that it is possible to suppress the upper-layer wiring 40 from being short-circuited to the lower-layer wiring 50 via the contact plug 31.

In this manner, according to the second embodiment, even if the misalignment occurs in the lithographic process at the time of forming the hard masks 70, it is possible to suppress each lower-layer wiring 50 from being short-circuited to the contact plug 30 by forming the sidewall insulating films 80 on sidewalls of each lower-layer wiring 50, respectively. Furthermore, it is possible to suppress each upper-layer wiring 40 from being short-circuited to the contact plug 31 because the width Wtr of each trench TR is formed larger in light of the film thickness of the sidewall insulating films 80.

### Modification of Second Embodiment

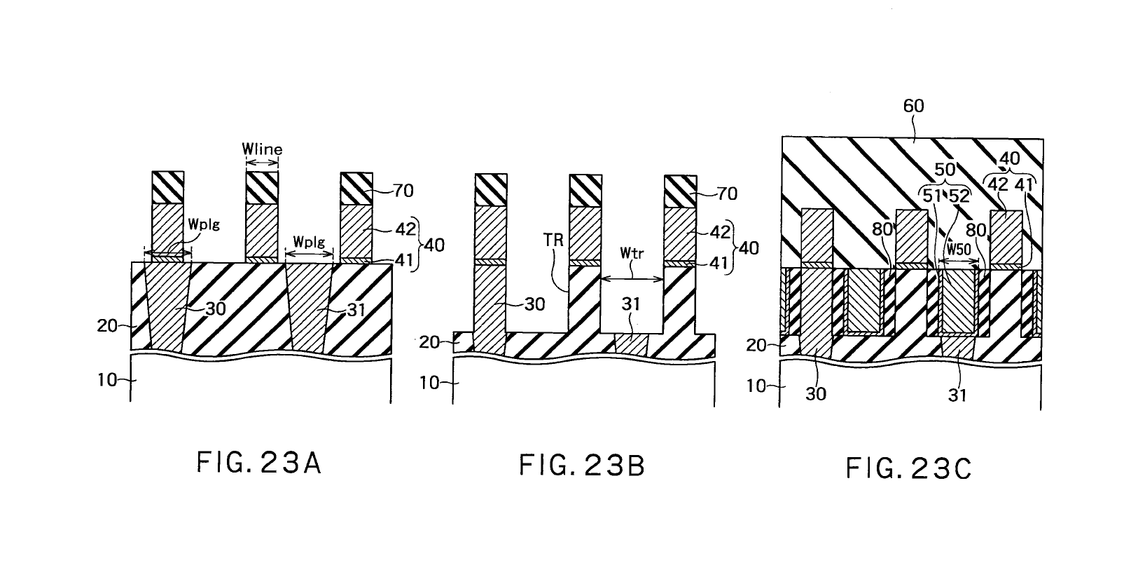

FIGS. 23A to 23C are cross-sectional views showing a manufacturing method of a memory device according to a modification of the second embodiment. In the modification, as shown in FIG. 23A, a diameter Wplg of an upper surface of each of the contact plugs 30 and 31 is larger than the width Wline of each upper-layer wiring 40. The diameter Wplg of the upper surface of each of the contact plugs 30 and 31 is also larger than the width W50 of each lower-layer wiring 50. For example, when assuming that the width Wline of the upper-layer wiring 40 is 20 nm and that the width W50 of the lower-layer wiring 50 is 30 nm, the diameter Wplg of the upper surface of each of the contact plugs 30 and 31 is, for example, about 35 nm.

On the other hand, to suppress the contact between each upper-layer wiring 40 and the contact plug 31, the diameter Wplg of the upper surface of each of the contact plugs 30 and 31 is made smaller than the distance Wtr between the adjacent upper-layer wirings 40 (opening width of each trench TR).

Using the hard masks 70 and/or the upper-layer wirings 40 as masks, the lower-layer insulating film 20 is etched and the trenches TR are formed in a self-aligned manner as shown in FIG. 23B. The diameter Wplg of the upper surface of each of the contact plugs 30 and 31 is larger than the width W50 of each lower-layer wiring 50. Therefore, each contact plug 30 protrudes outward of the bottom of the upper-layer wiring 40, so that the contact plug 30 is in a state of being exposed to the inner side surfaces and the bottoms of the trenches TR.

On the other hand, because the diameter Wplg of the upper surface of each contact plug 31 is smaller than the distance Wtr between the adjacent upper-layer wirings 40 (the opening width of each trench TR), each upper-layer wiring 40 does not protrude to the upper surface of the contact plug 31. That is, the entire upper surface of each contact plug 31 is exposed. Therefore, each contact plug 31 is removed by as much as the depth corresponding to the position of the bottom of each trench TR.

As shown in FIG. 23C, the sidewall insulating films 80 and the lower-layer wiring 50 are formed in each trench TR. The film thickness of each sidewall insulating film 80 is, for example, about 10 nm.

In the case of filling the material of the lower-layer wirings 50 in each trench TR without forming the sidewall insulating films 80, each lower-layer wiring 50 contacts the contact plug 30 on the inner side surface and the bottom of the trench TR. This causes the lower-layer wiring 50 to be short-circuited to the upper-layer wiring 40 via the contact plug 30.

On the other hand, according to the modification, each sidewall insulating film 80 is provided between one inner side surface of each trench TR and one side surface of each lower-layer wiring 50 as shown in FIG. 23C. Furthermore, the sidewall insulating film 80 also covers the end portion of the bottom of each trench TR. Therefore, the sidewall insulating film 80 can suppress each lower-layer wiring 50 from being short-circuited to the contact plug 30.

Furthermore, in the modification, the width Wtr of each trench TR is formed larger than the width Wplg of each contact plug 31. Therefore, each upper-layer wiring 40 is not arranged on the contact plug 31. The contact plug 31 is thereby removed by as much as the depth corresponding to the position of the bottom of each trench TR, so that it is possible to suppress the upper-layer wiring 40 from being short-circuited to the lower-layer wiring 50 via the contact plug 31.

In this manner, according to the modification, even if the width Wplg of the upper surface of each of the contact plugs 30 and 31 is made larger, it is possible to suppress each lower-layer wiring 50 from being short-circuited to the contact plug 30 by forming the sidewall insulating films 80 on the sidewalls of each lower-layer wiring 50, respectively. Furthermore, it is possible to suppress each upper-layer wiring 40 from being short-circuited to the contact plug 31 even if the width Wplg of the upper surface of each of the contact plugs 30 and 31 is made larger. This is because the width Wtr of each trench TR is formed larger in light of the film thickness of the sidewall insulating films 80.

Further, according to the modification, because the width Wplg of the upper surface of each of the contact plugs 30 and 31 is larger, a contact area between each upper-layer wiring 40 and the contact plug 30 and that between each lower-layer wiring 50 and the contact plug 31 inevitably increase. It is thereby possible to lower a contact resistance between each upper-layer wiring 40 and the contact plug 30 and that between each lower-layer wiring 50 and the contact plug 31.

### Third Embodiment

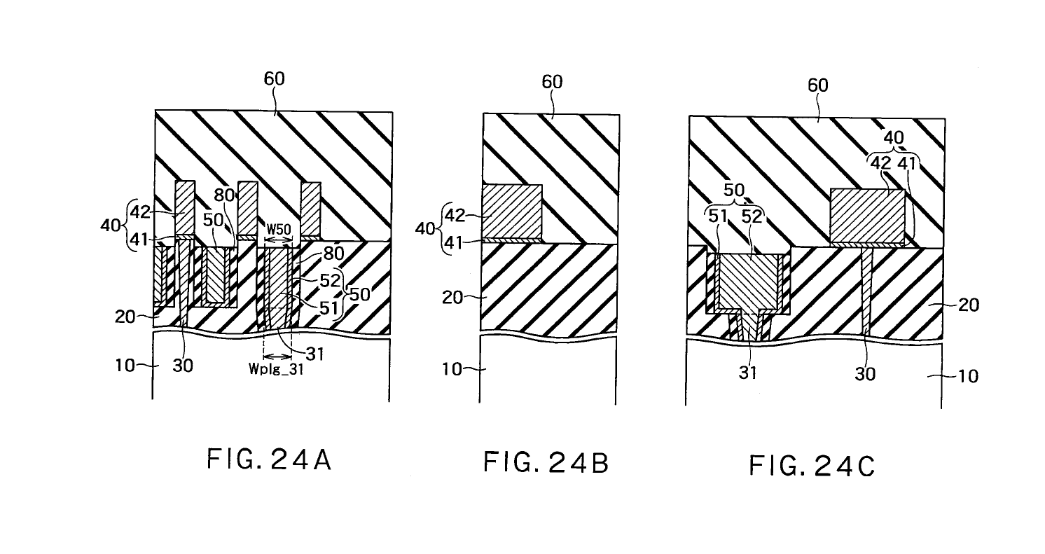

FIGS. 24A to 24C are cross-sectional views showing an example of a configuration of a memory device according to the third embodiment.

In the third embodiment, a width Wplg_{—}31 of each contact plug 31 is substantially equal to the width W50 of each lower-layer wiring 50 in the memory region. Other configurations of the third embodiment can be identical to corresponding ones of the first or second embodiment. When the third embodiment is combined with the first embodiment, the sidewall insulating films 80 to be described later are not formed.

By making the width Wplg_{—}31 of each contact plug 31 substantially equal to the width W50 of each lower-layer wiring 50, the contact resistance between each lower-layer wiring 50 and the contact plug 31 is lowered. The third embodiment can also achieve effects identical to those of the second embodiment.

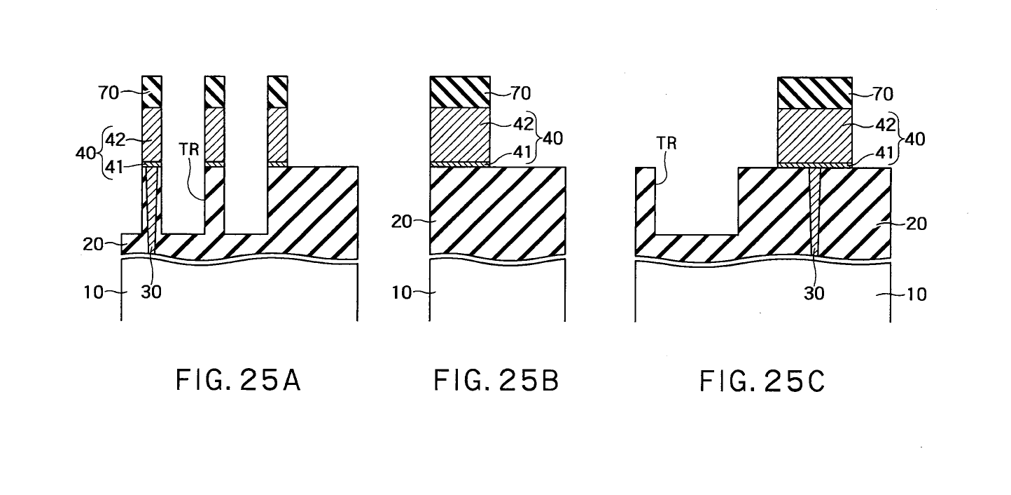

FIGS. 25A to 28C are cross-sectional views showing a manufacturing method of the memory device according to the third embodiment. FIGS. 25A, 26A, 27A, and 28A correspond to FIG. 24A, FIGS. 25B, 26B, 27B, and 28B correspond to FIG. 24B, and FIGS. 25C, 26C, 27C, and 28C correspond to FIG. 24C.

First, the trenches TR are formed similarly to the first embodiment after performing the processes shown in FIGS. 3-1 to 10C. However, in the third embodiment, the contact plugs 31 are not formed yet although the contact plugs 30 are formed.

A cross-sectional structure shown in FIGS. 25A to 25C is thereby obtained. Specific examples of the width and the height of each of the upper-layer wirings 40 can be made equal to those of each of the upper-layer wirings 40 in the first embodiment. The pitch Wpitch of the upper-layer wirings 40 in the memory region is, for example, about 70 nm. The width Wline of each upper-layer wiring 40 is, for example, about 20 nm. The width Wtr of each trench TR is, for example, about 50 nm. In the third embodiment, because the sidewall insulating films 80 are formed on the inner side surfaces of each trench TR, respectively similarly to the second embodiment, it is necessary to make the width Wtr of each trench TR larger than the desired width of each lower-layer wiring 50 in light of the widths of the sidewall insulating films 80. When assuming that the width of each lower-layer wiring 50 is W50 and that of each sidewall insulating film 80 is W80, the width Wtr of each trench TR is W50+2×W80. For example, when assuming that the width W50 of the lower-layer wiring 50 is 30 nm and that the width W80 of the sidewall insulating film 80 is 10 nm, the width Wtr of the trench TR is 50 nm. As described above, the sidewall insulating films 80 are not formed when the third embodiment is combined with the first embodiment.

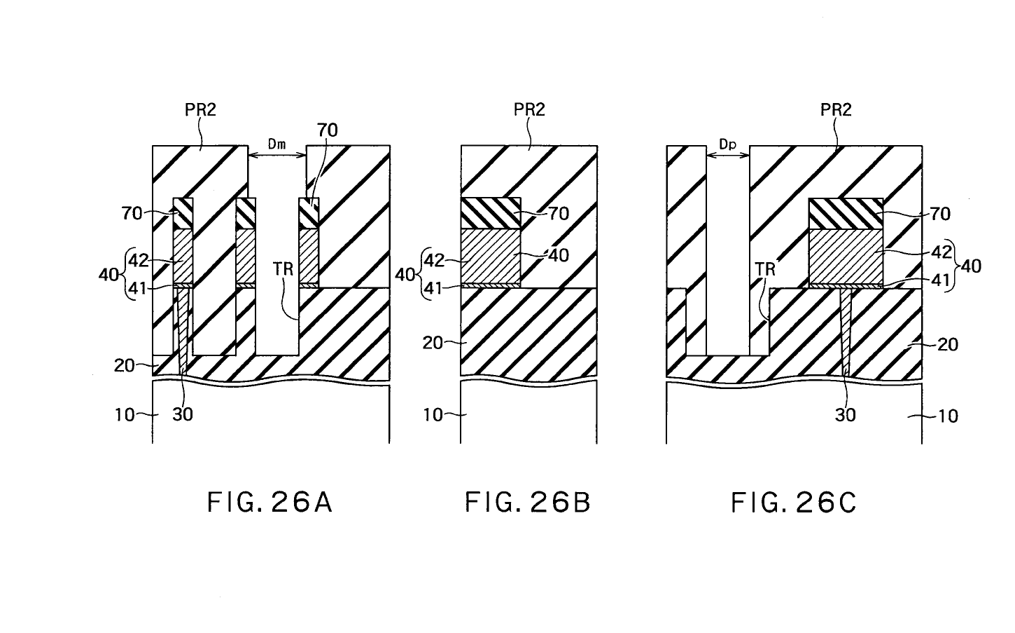

Next, as shown in FIGS. 26A to 26C, a photoresist PR2 (a second mask) is applied and patterned using the lithographic technique. At this time, the photoresist PR2 present in regions of forming the contact plugs 31 is removed and the other regions are covered with the photoresist PR2. At this time, as shown in FIG. 26A, in the memory region, the photoresist PR2 is patterned so as to expose a part of upper portions of the hard masks 70. With this configuration, in the cross-section in the second direction, the width of each of the lower-layer wirings 50 and that of each of the contact plugs 31 can be formed substantially equally. In such a region that needs a fine processing as the memory region, it is possible to lower the contact resistance by forming the width of each lower-layer wiring 50 to be substantially equal to that of each contact plug 31.

On the other hand, as shown in FIG. 26C, in the peripheral circuit region, in the cross-section in the second direction, the photoresist PR2 is formed to be narrower than each trench TR. The photoresist PR2 covers the inner side surfaces of each trench TR and is patterned so as to expose a part of the bottom of the trench TR. With this configuration, in the cross-section in the second direction, each lower-layer wiring 50 is made narrower than each contact plug 31.

A shape of each opening of the photoresist PR2 is, for example, a circular shape. In the memory region, a diameter Dm of the opening of the photoresist PR2 is, for example, about 55 nm. In the peripheral circuit region, a diameter Dp of the opening of the photoresist PR2 is, for example, about 50 nm.

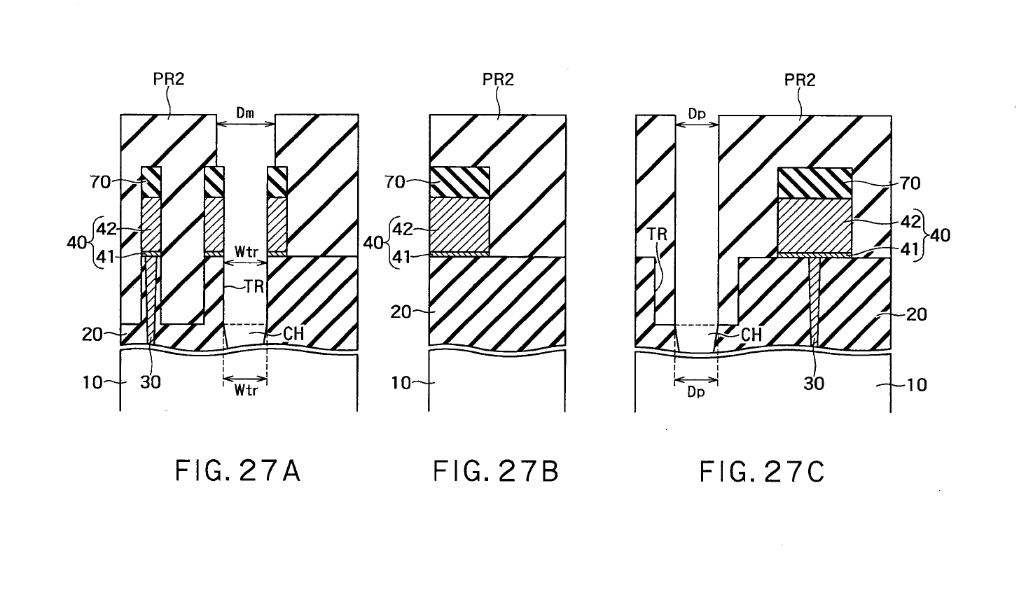

Next, using the photoresist PR2 and the hard masks 70 (and/or the metal films 41 and 42) as masks, the lower-layer insulating film 20 is etched by the dry etching method. As shown in FIGS. 27A to 27C, contact holes CH are thereby formed. Each of the contact holes CH is formed at a position of each contact plug 31 and formed to reach the semiconductor element present under the position.

At this time, in the cross-section in the second direction, the diameter Dm of each opening of the photoresist PR2 is larger than the width Wtr of each trench TR in the memory region. Therefore, each contact hole CH is formed in the second direction in a self-aligned manner. As a result, as shown in FIG. 27A, a diameter of an upper end of the contact hole CH (the width in the cross-section in the second direction) is substantially equal to the width Wtr of each trench TR.

Furthermore, in the cross-section in the second direction in the memory region, the photoresist PR is patterned so as to expose a part of the upper surfaces of the hard masks 70. Therefore, even if misalignment occurs in the lithographic process, the misalignment does not adversely effect the formation of the contact holes CH as long as an end of the photoresist PR2 is present on the upper surfaces of the hard masks 70.

On the other hand, the diameter Dp of each opening of the photoresist PR2 in the peripheral circuit region is smaller than the width of each trench TR. Therefore, the contact holes CH are formed in accordance with patterns of the photoresist PR2 in the second direction. As a result, as shown in FIG. 27C, the diameter of the upper end of each contact hole CH (the width in the cross-section in the second direction) in the peripheral circuit region is formed to be smaller than the width of each trench TR in the peripheral circuit region.

Furthermore, in the cross-section in the second direction in the peripheral circuit region, the photoresist PR2 is patterned so as to expose a part of the bottom of each trench TR. Therefore, even if misalignment occurs in the lithographic process, the misalignment does not adversely effect the formation of the contact holes CH as long as the end of the photoresist PR2 is present on the bottoms of the trenches TR.

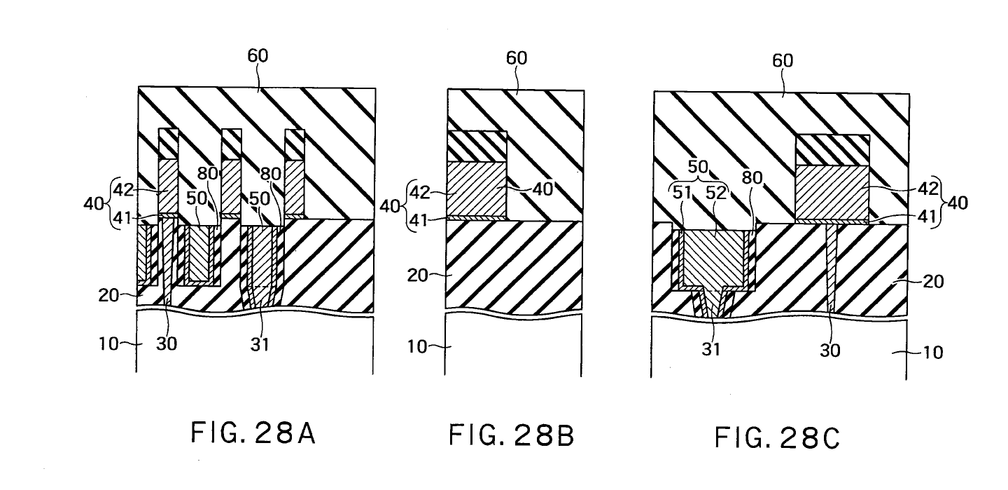

After removing the photoresist PR2, the sidewall insulating films 80 and the lower-layer wirings 50 are formed in the trenches TR and the contact holes CH similarly to the second embodiment. As shown in FIGS. 28A to 28C, the contact plugs 31 and the lower-layer wirings 50 are thereby formed. In this case, the materials of the sidewall insulating films 80 and the lower-layer wirings 50 (the titanium nitride film and the tungsten film, for example) are filled not only in the trenches TR but also in the contact holes CH either continuously or simultaneously.

With this configuration, the contact plugs 31 electrically connected to the semiconductor elements are formed and the lower-layer wirings 50 are formed either continuously or simultaneously.

In the third embodiment, the upper surface of each contact plug 31 can be formed so as to have a diameter substantially equal to the width W50 of each lower-layer wiring 50. Therefore, each contact plug 31 can make the contact area between the contact plug 31 and the lower-layer wiring 50 larger and can lower the contact resistance therebetween.

Furthermore, in the third embodiment, the contact holes CH are formed in the second direction in a self-aligned manner. This can prevent each contact plugs 31 from being displaced with respect to the lower-layer wiring 50 in the second direction. Therefore, even if misalignment occurs in the lithographic process to some extent at the time of forming the hard masks 70, it is possible to suppress each upper-layer wiring 40 from being short-circuited to the contact plug 31.

The third embodiment can achieve effects identical to those of the second embodiment.

In the third embodiment, the contact holes CH are formed after forming the trenches TR. However, the contact holes CH can be formed before forming the trenches TR. Even in this case, effects of the third embodiment are not lost. For example, a mask of the photoresist PR2 is formed into layout patterns of the contact plugs 31 before forming the trenches TR, and the lower-layer insulating film 20 is removed using the photoresist PR2 and the hard masks 70 (and/or the metal films 41 and 42) as masks. In this way, the contact holes b CH can be formed before forming the trenches TR. Even in this case, the contact holes CH are formed in a self-aligned manner using a part of the hard masks 70 (and/or the metal films 41 and 42).

Further, the contact holes CH can be formed halfway in the lower-layer insulating film 20 before forming the trenches TR, and the contact holes CH can be formed so as to penetrate the lower-layer insulating film 20 simultaneously with the time of forming the trenches TR. For example, the mask of the photoresist PR2 is formed into the layout patterns of the contact plugs 31 before forming the trenches TR, and the contact holes CH are formed halfway by removing an upper portion of the lower-layer insulating film 20 using the photoresist PR2 and the hard masks 70 (and/or the metal films 41 and 42) as the masks. At the time of forming the trenches TR, the trenches TR and the contact holes CH are formed simultaneously. In this way, the contact holes CH can be formed simultaneously with the trenches TR. Even in this case, the contact holes CH are formed in a self-aligned manner using a part of the hard masks 70 (and/or the metal films 41 and 42). Furthermore, in this case, the manufacturing processes of the memory device can be shortened because of the either simultaneous or continuous performing of a process of forming the trenches TR and a part of a process of forming the contact holes CH.

The first to third modifications of the first embodiment can be applied to the second or third embodiment. Accordingly, the second or third embodiment can also achieve effects of the first to third modifications of the first embodiment.

Furthermore, the modification of the second embodiment can be applied to the third embodiment. Accordingly, the third embodiment can also achieve effects of the modification of the second embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a semiconductor substrate;
an insulating film provided above the semiconductor substrate;
a plurality of upper-layer wirings provided on the insulating film; and
a plurality of lower-layer wirings provided in the insulating film, wherein
when viewed from above the semiconductor substrate, the lower-layer wirings are respectively located between the upper-layer wirings adjacent to each other, and
when viewed from above the semiconductor substrate, side surfaces of the lower-layer wirings substantially match side surfaces of the upper-layer wirings present on both sides of the lower-layer wirings, respectively.

2. The device of claim 1, wherein the lower-layer wirings protrude farther than the upper-layer wirings in an extension direction of the upper-layer wirings, on end portions of the lower-layer wirings.

3. The device of claim 1, wherein upper surfaces of the lower-layer wirings are located at a lower position than bottom surfaces of the upper-layer wirings.

4. The device of claim 1, wherein the upper-layer wirings and the lower-layer wirings are alternately arranged and constitute a two-layer wiring structure.

5. The device of claim 1, wherein
trenches are present in the insulating film in such a manner that the trenches are respectively located between the upper-layer wirings adjacent to each other when viewed from above the semiconductor substrate,
inner side surfaces of the trenches substantially match side surfaces of the upper-layer wirings present on both sides of the respective trenches when viewed from above the semiconductor substrate, and
the lower-layer wirings are provided in the trenches.

6. The device of claim 5, wherein widths of the trenches are larger than widths of the upper-layer wirings.

7. The device of claim 6, further comprising a sidewall insulating film on inner side surfaces of the trenches, wherein
the lower-layer wirings are provided in the trenches via the sidewall insulating film.

8. The device of claim 1, further comprising an interlayer dielectric film provided between and on the upper-layer wirings, wherein an air gap is formed in the interlayer dielectric film present between the upper-layer wirings adjacent to each other.

9. The device of claim 1, further comprising contact plugs provided under the lower-layer wirings, wherein widths of upper surfaces of the contact plugs are substantially equal to widths of the lower-layer wirings in a cross-section in an orthogonal direction to an extension direction of the lower-layer wirings.

10. A semiconductor device comprising:
a semiconductor substrate;
an insulating film provided above the semiconductor substrate;
a plurality of upper-layer wirings provided on the insulating film; and
a plurality of lower-layer wirings provided in the insulating film, wherein
the upper-layer wirings and the lower-layer wirings are alternately arranged and constitute a two-layer wiring structure, and
the lower-layer wirings protrude farther than the upper-layer wirings in an extension direction of the upper-layer wirings.

11. A manufacturing method of a semiconductor device comprising:
forming a first metal film on an insulating film present above a semiconductor substrate;
forming a first mask on the first metal film;
forming a plurality of upper-layer wirings by etching the first metal film using the first mask as a mask;
forming trenches between the upper-layer wirings adjacent to each other by etching the insulating film using either the first mask or the first metal film as a mask; and
forming lower-layer wirings in a self-aligned manner by filling a second metal film in the trenches, so that the lower-layer wirings are located between the upper-layer wirings adjacent to each other when viewed from above the semiconductor substrate.

12. The method of claim 11, wherein side surfaces of the lower-layer wiring substantially match side surfaces of the upper-layer wirings present on both sides of the lower-layer wiring, respectively when viewed from above the semiconductor substrate.

13. The method of claim 11, wherein the lower-layer wirings protrude farther than the upper-layer wirings in an extension direction of the upper-layer wirings, on end portions of the lower-layer wirings.

14. The method of claim 11, wherein the upper-layer wirings and the lower-layer wirings are alternately arranged and constitute a two-layer wiring structure.

15. The method of claim 11, wherein
a sidewall insulating film is formed on inner side surfaces of the trenches after forming the trenches, and
the second metal film is filled in the trenches after forming the sidewall insulating film.

16. The method of claim 11, further comprising:
providing an interlayer dielectric film between and on the upper-layer wirings, wherein an air gap is formed in the interlayer dielectric film present between the upper-layer wirings adjacent to each other.

17. The method of claim 15, further comprising forming contact plugs formed in the insulating film before forming the first metal film, wherein diameters of upper surfaces of the contact plugs are larger than widths of the upper-layer wirings.

18. The method of claim 11, comprising
forming a second mask into a layout pattern of lower-layer contact plugs to be formed under the trenches, and forming contact holes by removing the insulating film using the second mask and the first mask or the first metal film as a mask in order to form the lower-layer contact plugs before forming the trenches, or
forming the second mask exposing at least a part of the trenches and covering remaining portions of the trenches, and forming contact holes by further removing the insulating film on bottoms of the trenches using the second mask and the first mask or the first metal film as the mask in order to form the lower-layer contact plug to be formed under the trenches after forming the trenches, wherein
the lower-layer contact plugs as well as the lower-layer wirings are formed by filling the second metal film in the trenches and in the contact holes, in the forming of the lower-layer wirings.

19. The method of claim 11, comprising forming a second mask into a layout pattern of lower-layer contact plugs to be formed under the trenches, and forming contact holes halfway by removing an upper portion of the insulating film using the second mask and the first mask or the first metal film as a mask in order to form the lower-layer contact plugs before forming the trenches, wherein
the trenches and the contact holes are simultaneously formed when forming the trenches, and
the lower-layer contact plugs and the lower-layer wirings are formed by filling the second metal film in the trenches and in the contact holes in the forming the lower-layer wirings.

20. The method of claim 18, wherein the contact holes are formed using the first mask or the first metal film as the mask, and
opening diameters of the contact holes are substantially equal to widths of the trenches in the cross-section in the orthogonal direction to the extension direction of the lower-layer wirings.
